(19) United States
(12) Patent Application Publication
(10) Pub. No.: US 2010/0230142 A1
(43) Pub. Date: Sep. 16, 2010

(54) METHOD FOR MANUFACTURING PRINTED WIRING BOARD

(75) Inventors: Keita Bamba, Chiba (JP); Tadahiro Yokozawa, Chiba (JP); Hideaki Watanabe, Chiba (JP)

Correspondence Address: KNOBBE MARTENS OLSON & BEAR LLP, 2040 MAIN STREET, FOURTEENTH FLOOR, IRVINE, CA, 92614, US

(73) Assignee: UBE INDUSTRIES, LTD., Yamaguchi,jp (JP)

(21) Appl. No.: 12/739,369

(22) PCT Filed: Oct. 23, 2008
(86) PCT No.: PCT/JP2008/069238

§ 371 Date: Apr. 22, 2010

(30) Foreign Application Priority Data
Oct. 23, 2007 (JP) 2007-275402

(51) Int. Cl. H05K 1/03; B32B 38/10

(52) U.S. Cl. 174/255; 156/153

(57) ABSTRACT

Disclosed is a method for producing a printed wiring board having high dimensional stability with high productivity. The production method comprising the steps of: providing a metal laminate in which a metal layer having an inner metal layer portion and a protection layer portion is laminated on at least one side of an insulating resin layer in such a manner that the inner metal layer portion is arranged on the side of the insulating resin layer; forming a via hole on the metal layer and the insulating resin layer; performing blast processing after forming the via hole; and removing the protection layer portion after performing blast processing.

### TECHNICAL FIELD

The present invention relates to a method for producing a printed wiring board having a via hole.

### BACKGROUND ART

Since copper foil laminated polyimide films have excellent properties such as thinness and lightness in weight, they have been used for high-performance electronic devices, in particular, flexible printed circuit boards (FPC), tape automated bonding (TAB) or the like with high-density wirings which are suitable for reduction in size and weight. With the high density integration and fining of the electronic devices, wiring boards have been in demand to respond to high-density mounting. Double-sided wiring boards and multi-layer wiring boards have been proposed as a wiring board to response to high-density mounting. In order to produce such double-sided and multi-layer wiring boards, the formation of via holes with high productivity have been required.

In general, it is necessary to remove burr and clean (desmear) the inside of the via hole after the step of forming a via hole. Patent Document 1 discusses that buff-polishing used for removing burr of a metal causes anisotropic dimensional change in the processed substrate; a dry blasting method causes a problem of dust; an aqueous alkaline permanganate solution used for cleaning (desmear) of a polyimide portion in the via hole easily causes cracks in a polyimide layer; and there is a defect caused by bad adhesion between a metal layer and a plated copper layer due to these method of pretreating conducted before via hole-plating. Further, Patent Document 1 discloses, as the method of pretreating conducted before via hole-plating with high productivity, a wet blasting method to remove burr of the metal caused by the formation of the via hole and to clean (desmear treatment) the inside of the hole after forming the via hole on at least one side of the metal layer and the polyimide layer.

Specifically, this document discloses “in a double-sided flexible substrate using a double-sided metal foil laminate obtained by thermo-compression bonding electrolytic copper foils (thickness: 9 μm) onto both sides of a polyimide film (thickness: 25 μm) and obtained by the wet blast treatment, a copper foil and a copper plating layer are sufficiently bonded to each other, and the anisotropy hardly observed, since the extension ratio in the width direction before and after wet blasting is 0.092% and the extension ratio in the transport direction is 0.096%”.

However, if the metal layer is further thinned in order to pursue fine pitches, the extension easily occurs in a base material due to the wet blast treatment, and if the extension occurs anisotropically in the direction, positioning in the photolithography process and positioning of inner leads and bumps in semiconductor chip mounting process become difficult in some cases. Accordingly, a method for producing a printed wiring board having high dimensional stability has been in demand even though the base material with thin metal layer is subjected to the wet blast treatment.

Patent Document 2 discloses, as a step of producing a printed wiring board including the formation of a via hole on an insulating resin composition layer laminated with sheets of copper foil with carrier, a method comprising peeling off carrier foil(s) after drilling by an irradiation with a laser from the top of sheets of copper foil with carrier (see Paragraph Nos. 0040 and 0041). However, in the desmear treatment, use of an aqueous alkaline permanganate solution is only described (see Paragraph No. 0071), but the blast treatment, particularly the wet blast treatment, is not described.

Patent Document 1: Japanese Laid-open Patent Publication No. 2003-318519

Patent Document 2: Japanese Laid-open Patent Publication No. 2004-335784

### DISCLOSURE OF THE INVENTION

### Problems to be Solved by the Invention

An object of the present invention is to provide a method for producing a printed wiring board having high dimensional stability with high productivity.

### Means for Solving the Problems

The present invention is directed to the following items.

1. A method for producing a printed wiring board comprising the steps of:

providing a metal laminate in which a metal layer having an inner metal layer portion and a protection layer portion is laminated on at least one side of an insulating resin layer in such a manner that the inner metal layer portion is arranged on the side of the insulating resin layer;

forming a via hole on the metal layer and the insulating resin layer;

performing blast processing after forming the via hole; and

removing the protection layer portion after performing blast processing.

2. The method according to the above item 1, wherein the metal layer has a structure in which the inner metal layer portion and the protection layer portion are being laminated as different layers, and the protection layer portion is removed by peeling off or etching at the step after performing blast processing.
3. The method according to the above item 2, wherein the protection layer portion is selected from the group consisting of resin, metal, or a multi-layer structure of a resin and a metal.
4. The method according to the above item 2, wherein the metal layer is a copper foil with carrier foil.
5. The method according to the above item 1, wherein in the metal layer, the inner metal layer portion and the protection layer portion are present as a single layer that cannot be distinguished from each other, and the protection layer portion is removed by etching.
6. The method according to any one of the above items 1 to 5, wherein a thickness of the protection layer portion is determined such that the absolute value of the dimensional change ratio just after removing the protection layer portion is not more than 0.07% as compared to the dimension measured just after forming the via hole.
7. The method according to any one of the above items 1 to 5, wherein a thickness of the protection layer portion is determined such that the absolute value of the dimensional change ratio when completing a wiring pattern is not more than 0.07% as compared to the dimension measured just after forming the via hole.
8. The method according to any one of the above items 1 to 7, wherein a thickness of the protection layer portion is not less than 2 μm.
9. The method according to any one of the above items 1 to 8, wherein the metal laminate has the metal layers laminated on both sides of the insulating resin layer, and after removing the protection layer, formation of the wiring pattern and electrical connection between wirings present on both sides of the insulating resin layer through the via hole are carried out.
10. The method according to any one of the above items 1 to 9, wherein the insulating resin layer is obtained by laminating a thermo-compression bonding polyimide layers on both sides of a high heat resistant aromatic polyimide layer into one body.
11. A copper wiring polyimide film produced by the method according to the above item 10.

### EFFECT OF THE INVENTION

According to the present invention, in a production method comprising blast processing, particularly a wet blast treatment, that is a highly productive method of pretreating for via hole-plating, it is possible to suppress extension of the base material which becomes problematic when a copper foil is thinned. Accordingly, there is provided a method for producing a printed wiring board having high dimensional stability with high productivity.

In the production method of the present invention, since the dimensional change ratio during all steps are small, a positional relationship between the via hole location and the wiring pattern location, and a positional relationship between locations of bumps and inner leads of a semiconductor chip are accurate. Therefore, it is possible to provide a printed wiring board with high accuracy.

### BRIEF DESCRIPTION OF THE DRAWINGS

FIG. 1A is a process chart illustrating an example of a process for production of a double-sided copper wiring polyimide film by means of a semi-additive method using a double-sided copper foil laminated polyimide film with carrier.

FIG. 1B is a process chart illustrating an example of the process for production of a double-sided copper wiring polyimide film by means of a semi-additive method using a double-sided copper foil laminated polyimide film with carrier, subsequently to FIG. 1A.

FIG. 2A is a process chart illustrating an example of a process for production of a double-sided copper wiring polyimide film by means of a subtractive method using a double-sided copper foil laminated polyimide film with carrier.

FIG. 2B is a process chart illustrating an example of the process for production of a double-sided copper wiring polyimide film by means of a subtractive method using a double-sided copper foil laminated polyimide film with carrier, subsequently to FIG. 2A.

FIG. 3 is a process chart illustrating an example of the process for production step until a through hole is formed from a double-sided copper foil laminated polyimide film with carrier using a double-sided copper foil laminated polyimide film with carrier.

FIG. 4 is a process chart illustrating an example of the process for production of a multi-layer copper wiring polyimide film.

FIG. 5 is a graph with a horizontal axis indicating steps and with a vertical axis indicating dimensional change ratios in Table 1.

FIG. 6 is a view showing locations of reference points for measuring the dimensional change ratio.

FIG. 7 is a process chart illustrating Embodiment 5.

### EXPLANATION OF THE REFERENCES

1: Double-sided copper foil laminated polyimide film with carrier
2: Polyimide film
3, 3′: copper foil with carrier or copper foil (Embodiment 5)
4, 4′: Copper foil or copper foil having an inner metal layer portion (Embodiment 5)
5, 5′: Carrier foil (protection layer)
6: Via hole
7: Metal burr and metal smear, and resin burr and resin smear
8: Conductive film
9, 9′: Photoresist layer
10, 10′: Conductive film surface emerged after developing and removing the photoresist
11, 11′: Patterned copper plating
12, 12′: Polyimide film surface emerged after removing the copper foil by flash etching
13, 13′: Metal plating
21, 21′: Paneled copper plating
22, 22′: Copper plating surface emerged after developing and removing the photoresist
23, 23′: Polyimide film surface emerged after removing the copper foil by etching
42: polyimide film
43: Copper foil with carrier
44: Copper foil
45: Carrier foil (protection layer)
46: Via hole
48: Conductive film
51: Patterned copper plating
101: Double-sided copper foil laminated polyimide film with carrier
102: Double-sided copper foil laminated polyimide film with carrier having a via hole formed thereon which does not penetrate the carrier foil on one side
103: Double-sided copper wiring polyimide film with a circuit formed by means of a semi-additive method
104: Double-sided copper wiring polyimide film subjected to metal plating on both sides of 103
112: Double-sided copper foil laminated polyimide film with carrier having a via hole formed thereon which does not penetrate the copper foil with carrier on one side
113: Double-sided copper wiring polyimide film with a circuit formed by means of a subtractive method
114: Double-sided copper wiring polyimide film subjected to metal plating on both sides of 113
122: Double-sided copper foil laminated polyimide film with carrier with a through hole formed thereon
401: One-sided copper foil laminated polyimide film with carrier

### BEST MODE FOR CARRYING OUT THE INVENTION

The metal laminate used in the present invention has a structure in which a metal layer having an inner metal layer portion and a protection layer portion are laminated on both sides of an insulating resin layer such a manner that the inner metal layer portions are arranged on the side of the insulating resin layer. The protection layer portion is to protect the inner metal layer portion from blast processing, particularly a wet blast treatment, and is removed at a step after performing blast processing. The inner metal layer portion is a part remained after the removal of the protection layer portion.

In the first embodiment, the metal layer having an inner metal layer portion and a protection layer portion has a structure obtained by laminating the inner metal layer portion and the protection layer portion as different layers. Examples thereof include protection layer-accompanied metal foils such as copper foils with carrier and the like. In the second embodiment, the metal layer having an inner metal layer portion and a protection layer portion may be a single layer, in which the inner metal layer portion and the protection layer portion are not distinguished from each other as different layers, wherein the outer portion of the metal layer may function as the protection layer portion and be removed at the step after performing blast processing, while the inner portion of the metal layer may function as the inner metal layer portion and remain after the step of removing the protection layer.

For the protection layer portion of the first embodiment, that is the metal layer is a laminate type layer, the materials thereof are not particularly restricted, but they may be those which can protect the inner metal layer from the wet blast treatment and be easily removed after performing the wet blast treatment. For example, aluminum foils, copper foils, polyimide films, polyethylene terephthalate films and the like may be used.

Any of insulating resin layers may be used as long as it is used as a substrate material for a printed wiring board, or it may be a composite materials. However, when the present invention is applied to those easily affected by the extension due to blast processing, the effect of the present invention can be more clearly exhibited; and therefore, a thin base material such as a film or the like is preferably used as the insulating resin layer. Particularly preferably used are polyimide films, polyester films, polyamide films, liquid crystal films and polyolefin films such as polypropylene, polyethylene or the like. The metal laminate may be those in which an insulating resin layer and an inner metal layer portion are laminated directly or through an adhesive layer. As adhesives, known adhesives may be used as long as it does not impair the object of the present invention and the use of the printed wiring board of the present invention.

A method of forming a metal laminate is not particularly restricted. For example, there may be used (i) a method in which, as a protection layers, metal foil or resin film having an adhesive layer or the like are further laminated on a laminate having metal layers (a portion corresponding to the inner metal layer portion) laminated on both sides of an insulating resin layer, (ii) a method in which metal layers with protection layer obtained by laminating protection layer and metal layer (inner metal layer portion) are laminated on an insulating resin layer, (iii) a method in which metal layers having protection layer portion which can be removed by etching or the like and inner metal layer portion as one body (the aforementioned second embodiment) are laminated on an insulating resin layer, and the like.

A method of removing a protection layer is not particularly restricted, but the protection layer may be removed in a simple method depending on the construction of the metal laminate with protection layer. In the first embodiment, for example, there may be used a method of peeling off the protection layer from the metal laminate with protection layer and a method of removing the protection layer by etching, while in the second embodiment, there may be used a method of removing the thickness corresponding to the protection layer of the metal layer by etching and the like.

The blast processing may be a dry blast treatment, but preferably used is a wet blast treatment since the dry blasting method is considered to cause a problem of dust. Examples of abrasive grains to be used for blasting include glass beads, alumina particles, silicon carbide, stainless powder, steel powder and the like. Examples of abrasive grains to be used for wet blasting include alumina particles, silicon carbide and the like. For removal of metal burr generated at the step of forming a via hole and for cleaning of the inside of the via hole, suitably used are alumina particles. Further, a particle diameter of abrasive grain is preferably smaller than a diameter of the hole in order to enable cleaning of the inside of the hole. On the other hand, when the particle diameter is too small, abrasive grains become muddy and sticky, therefore, the diameter is preferably from 1 to 20 μm and more preferably from 1 to 10 μm, for the hole having a diameter of 20 to 200 μm, for example.

The protection layer portion improves the dimensional stability if it is at least present, and therefore the thickness thereof is thicker than 0. The thickness of the protection layer is preferably determined such that the absolute value of the dimensional change ratio is not more than 0.07% and particularly not more than 0.05% when a wiring pattern is completed as compared to the dimension at the time of formation of the via hole (equal to the dimension measured after formation of the via hole). It is also preferred that it is determined such that the absolute value of the dimensional change ratio is not more than 0.07% and particularly not more than 0.05% when a mask pattern is transferred by photolithography as compared to the dimension at the time of formation of the via hole. In addition, it is also preferred to determine the thickness of the protection layer such that the absolute value of the dimensional change ratio is not more than 0.07% and particularly not more than 0.05% after performing blast processing to remove the protection layer portion (in particular, after removing the protection layer portion and before performing the next treatment).

It is preferable that the aforementioned dimensional change ratios satisfy the above range in all in-plane directions of the metal laminate. When the insulating resin layer is composed of a polyimide film, the thickness of the protection layer portion is preferably determined so as to satisfy the above range in both directions of the transport direction (the transport direction at the time of production=reel winding direction) and the width direction.

Specifically, the thickness of the protection layer portion also depends on the materials, but it is usually not less than 2 μm, preferably not less than 4 μm and further preferably not less than 6 μm in order to remove the portion including large stress applied by the blast processing. The thickness of the protection layer may be thick, and for example, it is not more than 200 μm, preferably not more than 100 μm, more preferably not more than 50 μm and further preferably not more than 20 μm.

In case of the first embodiment, when the protection layer portion can be peeled off and removed, the protection layer may be thick. For example, its thickness is not more than 200 μm and preferably not more than 100 μm. When the protection layer in the first embodiment is removed by etching, and the protection layer portion in the second embodiment is removed by etching, it is preferable that the thickness is not excessively thick. For example, it is not more than 100 μm, preferably not more than 50 μm and more preferably not more than 20 μm.

Meanwhile, the thickness of the inner metal layer portion remained after removing the aforementioned protection layer portion is from 0.5 to 16 μm, preferably from 0.5 to 8 μm and further preferably from 0.5 to 5 μm. The inner metal layer portion may be further thinned in consideration of reduction in thickness and its circuit processability, after removing the protection layer portion. The thickness of the inner metal layer portion may be properly selected depending on a method for forming a circuit. However, when a protection layer is not provided, the thinner metal layer portion results in larger extension, and the stress reaches up to the insulating resin layer; therefore, the effect of the protection layer is more remarkable in the case that the metal layer portion to be remained is thinner. For example, when a circuit is formed by a semi-additive method, the thickness may be thinned to the range of 0.5 to 3 μm and preferably to the range of 0.5 to 2 μm. When a circuit is formed by a subtractive method, it is further effective when it is thinned to the range of 2 to 8 μm and preferably to the range of 2 to 5 μm.

Incidentally, in the present invention, the term “via hole” is used in the same meaning as “hole”, and used in the meaning of both through hole and hole which does not penetrate the film (i.e. blind hole or recess). Further, it is used in the meaning of electrical-connection hole in which a conductive material is formed (e.g., plated) inside of the via hole to enable electrical connection between metal layers in multi-layer in some cases.

Production of the copper wiring polyimide film will be hereinafter described with reference to the drawings as typical examples, but the present invention is not restricted to these cases. An example is described using a copper foil with carrier in which the protection layer portion is a carrier foil and the inner metal layer is a copper foil. In the following description, the protection layer portion may be simply referred to as “protection layer”, and the inner metal layer may be simply referred to as “metal layer”.

### Embodiment 1

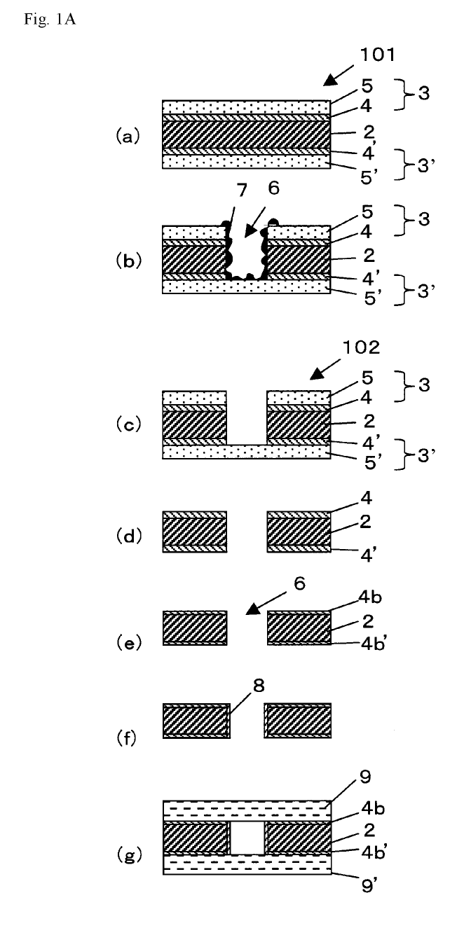

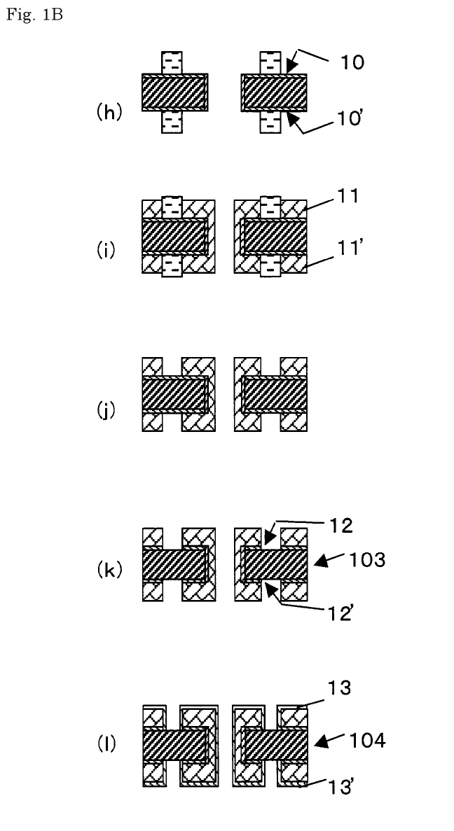

In this Embodiment, an example of the method for forming a circuit by means of a semi-additive method using a polyimide film laminated with sheets of copper foil with carrier on both sides thereof is illustrated in FIGS. 1A and 1B.

As shown in FIG. 1A(a), there is provided a polyimide film 101 laminated with sheets of copper foil with carrier on both sides thereof. This double-sided copper foil laminated polyimide film with carrier 101 contains a copper foil with carrier 3, a polyimide film 2 and a copper foil with carrier 3′ laminated in this order, wherein each copper foil with carrier (3, 3′) is respectively a laminate of each copper foil (4, 4′) and carrier foil (5, 5′) to be the protective layers. Herein, the thickness of the copper foil is in the range of 1 to 8 μm and preferably in the range of 1 to 6 μm.

In the next step, as shown in FIG. 1A(b), a via hole 6 is formed on a prescribed place of the double-sided copper foil laminated polyimide film with carrier 101, through the copper foil with carrier 3 on one side of the film, the polyimide film 2 and the copper foil 4′ by using a laser. A plurality of via holes may be formed. As shown in FIG. 1A(b), the via hole 6 may be formed as a hole reaching the carrier foil 5′ by removing the copper foil 4′ on the back side (to be a through hole after peeling off the carrier foil 5′), or as a through hole penetrating the copper foil with carrier 3′ including the carrier foil 5′ on the back side, or as a hole obtained by removing up to the polyimide film but leaving the copper foil 4′ on the back side. Various shapes can be formed.

After forming the via hole(s), particularly after forming the via hole(s) by laser processing, as shown in FIG. 1A(b), resin smear and resin burr, and metal smear and metal burr 7 appear inside the via hole 6 and at the periphery of the via hole on the surface of the copper foil with carrier 3. In the next step, the inside and the periphery of the via hole are cleaned by the wet blast treatment. The wet blast treatment can be performed in accordance with a well-known method, for example, a method described in Japanese Laid-open Patent Publication No. 2003-318519 (Patent Document 1). FIG. 1A(c) illustrates a double-sided copper foil laminated polyimide film with carrier 102 after performing cleaning by the wet blast treatment.

In the next step, as shown in FIG. 1A(d), the carrier foils 5 and 5′ as the protective layer are peeled off and removed from the polyimide film 102 laminated with sheets of copper foil with carrier on both sides thereof. As a result, there is obtained a double-sided copper foil laminated polyimide film in which the copper foil 4, the polyimide film 2 and the copper foil 4′ are directly laminated.

In the next step, as shown in FIG. 1A(e), etching (half etching) is performed to remove the release layers remained on the surfaces of the copper foils (4, 4′) of the double-sided copper foil laminated polyimide film. The thickness of the copper foil may be thinned to the range of 0.5 to 2 μm by half etching as necessary.

For half etching of the copper foil, a well-known method can be appropriately selected and carried out. For example, there can be used a method comprising dipping the copper foil laminated polyimide film into a well-known half etching solution or a method comprising spraying a half etching solution using a spray apparatus, to further thin the copper foil. As the half etching solution, the well-known ones can be used, and examples thereof include solutions in which hydrogen peroxide is mixed with sulfuric acid or solutions comprising sodium persulfate aqueous solution as a main ingredient. Examples thereof include DP-200 manufactured by Ebara-Udylite Co., Ltd. and ADEKA TEC CAP manufactured by Asahi Denka Kogyo K.K.

Then, as shown in FIG. 1A(f), conductive film (8) is formed on the polyimide surface of the via hole 6 of the double-sided copper foil laminated polyimide film and the copper foil 4b and the copper foil 4b′ are electrically connected.

In the next step, as shown in FIG. 1A(f), photoresist layers (9, 9′) are formed on the upper part of the half etched copper foil (4b, 4b′) of the double-sided copper foil laminated polyimide film, and subsequently, as shown in FIG. 1(h), the photoresist layer is exposed to light using the mask of a wiring pattern, followed by developing and removing a portion to be the wiring pattern. A plurality of the copper foil portion (10, 10′) to be the wiring pattern site is emerged from the opening section obtained by developing and removing the resist. Since the resist opening portion (resist removed part) corresponds to the wiring pattern, the opening portion is determined to have patterns, such as opening line width, pitch and the like, that enable the formation of a copper wiring part.

The photoresist may be a negative type and a positive type, and may be a liquid form, a film form or the like. Typically, the photoresist is formed on the copper foil by heat laminating the negative dry film-type resist, or applying and drying the positive liquid-type resist. In the case of the negative type, an unexposed site is removed by developing; on the other hand, in the case of the positive type, an exposed site is removed by developing. The thicker resist may be easily obtained for the dry film-type resist. For example, SPG-152 manufactured by Asahi Kasei Co., Ltd. and RY-3215 manufactured by Hitachi Chemical Co., Ltd. are exemplified as the negative dry film-type photoresist.

Furthermore, as the method to develop and remove the photoresist layer, known chemical(s) for developing and removing the photoresist layer can be appropriately selected. For example, a photoresist layer can be developed and removed by spraying sodium carbonate aqueous solution (1% etc.) and the like.

In the next step, as shown in FIG. 1B(i), copper plating layers (11, 11′) are formed on the upper part of the copper foil portions (10, 10′) immerged from the opening where the photoresist layers (9, 9′) are removed.

As the copper plating step, a known copper plating condition can be appropriately selected. For example, an exposed site of the copper foil is washed with an acid or the like, and electrolytic copper plating is carried our at a current density of 0.1 to 10 A/dm² with the copper foil as a cathode electrode in a solution typically comprising copper sulfate as a predominant constituent, whereby a copper layer is formed. As the electrolytic solution, there can be used a solution in which 180 to 240 g/l of copper sulfate, 45 to 60 g/l of sulfuric acid and 20 to 80 g/l of chlorine ion, and thiourea, dextrin or thiourea and molasses as additives are added.

In the next step (d), as shown in FIG. 1B(j), the photoresist layer 17 used as a plating resist is removed to expose the copper foil covered with the plating resist pattern layer.

In the next step, as shown in FIG. 1B(k), the copper foil exposed to a portion where the aforementioned plating resist pattern layer is removed is removed to expose a polyimide film surface 8. The thin copper foil is removed usually by flash etching. In this way, the double-sided copper wiring polyimide film can be produced. In FIG. 1B(k), sections where coppers are removed by etching in the double-sided copper wiring polyimide film 103 are assigned reference numbers of 12 and 12′. Copper wirings on both sides formed on the upper part of the hole of the double-sided copper wiring polyimide film 103 are being electrically connected.

As a flash etching solution used for flash etching, the well-known ones can be used, and examples thereof include solutions in which hydrogen peroxide is mixed with sulfuric acid or solutions comprising aqueous solutions of diluted ferric chloride as a main ingredient, for example, FE-830 manufactured by Ebara Densan Ltd. and AD-305E manufactured by Asahi Denka Kogyo K.K. Although here the copper of the circuit part (wiring) is dissolved when removing the thin copper foil, no substantial defect is made because the amount of etching necessary to remove the thin copper foil is small.

Furthermore, as shown in FIG. 1B(l), there is formed metal plating layers (13, 13′) in which at least a part of the copper wiring of the double-sided copper wiring polyimide film 103 is plated by tin plating or the like as needed, whereby a double sided copper wiring polyimide film 104 subjected to metal plating can be produced.

### Embodiment 2

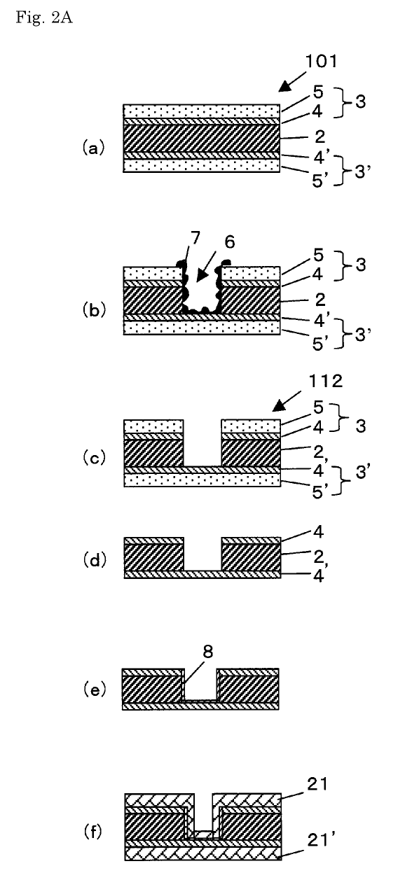

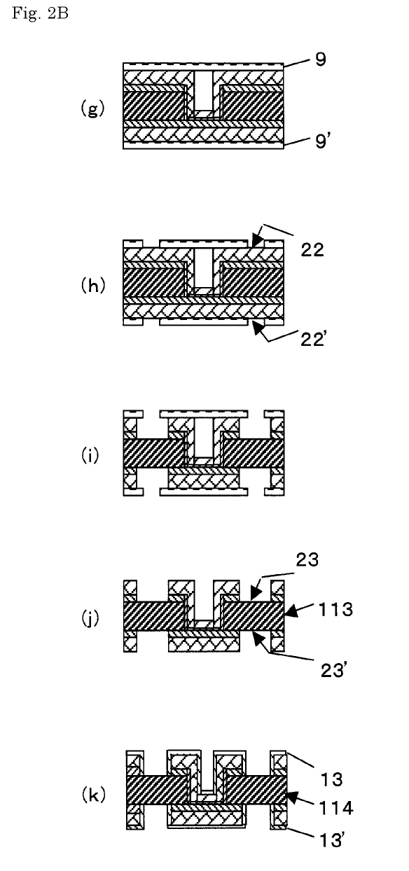

In this embodiment, FIGS. 2A and 2B illustrate an example of the process for forming a circuit by means of a subtractive method using a polyimide film laminated with sheets of copper foil with carrier on both sides.

As shown in FIG. 2A(a), there is provided a polyimide film 101 laminated with sheets of copper foil with carrier on both sides. In this double-sided copper foil laminated polyimide film 101, a copper foil with carrier 3, a polyimide film 2 and a copper foil with carrier 3′ are laminated in this order, while copper foils with carrier (3, 3′) are respectively a laminate of copper foils (4, 4′) and carriers (5, 5′). Herein, the thickness of the copper foil is in the range of 1 to 8 μm, preferably in the range of 1 to 6 μm.

In the next step, as shown in FIG. 2A(b), a via hole 6 is formed on a prescribed place of the double-sided copper foil laminated polyimide film with carrier 101, through the copper foil with carrier 3 on one side and the polyimide film 2 by using a laser. A plurality of via holes may be formed. As shown in FIG. 2B(b), the via hole 6 may be formed as a hole obtained by removing up to the polyimide film but leaving the copper foil 4′ on the back side, or as a hole reaching the carrier foil 5′ by removing the copper foil 4′ on the back side (to be a through hole after peeling off the carrier foil 5′), or as a through hole penetrating the copper foil with carrier 3′ including the carrier foil 5′ on the back side. Various shapes can be formed.

After forming the via hole(s), particularly after forming the via hole(s) by laser processing, resin smear and resin burr, and metal smear and metal burr 7 appear (FIG. 2A(b)). So, similarly to Embodiment 1, the inside of the via hole 6 and the periphery of the via hole on the surface of 3 are cleaned by the wet blast treatment to obtain a polyimide film 112 laminated with sheets of copper foil with carrier on both sides thereof having a via hole (FIG. 2A(c)).

In the next step, as shown in FIG. 2A(d), the carrier foil 5 and the carrier foil 5′, which are both protective layers, are peeled off from the double-sided copper foil laminated polyimide film with carrier 112, whereby obtaining a double-sided copper foil laminated polyimide film in which the copper foil 4, the polyimide film 2 and the copper foil 4′ are directly laminated. Usually, it is preferable to remove the release layers remained on the surfaces of the copper foils by half etching.

In the next step, as shown in FIG. 2A(e), a conductive film 8 is formed on the polyimide surface of the via hole 6 of the double-sided copper foil laminated polyimide film for electrically connecting the copper foil 4 and the copper foil 4′. In the next step, as shown in 2A(f), copper plating layers (21, 21′) are formed on the upper parts of the conductive film 8 and copper foils (4, 4′) of the double-sided copper foil laminated polyimide film. The step of copper plating is the same as that described in Embodiment 1.

In the next step, as shown in FIG. 2B(g), photoresist layers 9 and 9′ are formed on the upper parts of the copper plating layers of the double-sided copper foil laminated polyimide film. Then, as shown in FIG. 2B(h), the photoresist layers are exposed to light using the mask of a wiring pattern, followed by developing and removing a portion not to be the wiring pattern. A plurality of copper foil portions (22, 22′) not to be the wiring patterns are emerged from the opening portion where the resist has been removed by developing. Since the resist opening portion (resist removed portion) corresponds to the wiring pattern, the patterns, such as opening line width, pitch and the like, are determined so as to allow the formation of the copper wiring portion. The photoresist which can be used herein is the same as that described in Embodiment 1.

In the next step, as shown in FIG. 2B(i), the polyimide film is exposed by removing the copper foil portions (22, 22′) emerged from the opening where the photoresist layers (9, 9′) have been removed. The copper foils are usually removed by etching, and then as shown in FIG. 2B(j), the photoresist layers (9, 9′) used as the etching resist are removed to expose the copper foils covered with the etching resist pattern layers.

Thus, a double-sided copper wiring polyimide film 113 is produced. In FIG. 2B(j), sections where coppers are removed by etching in the double-sided copper wiring polyimide film 113 are assigned reference numbers of 23 and 23′. Copper wirings on both sides formed on the upper part of the hole of the double-sided copper wiring polyimide film 113 are being electrically connected.

As an etching solution used for etching, the known ones can be used, and examples thereof include an aqueous ferric chloride solution, an aqueous copper chloride solution, an aqueous ammonium persulfate solution, an aqueous sodium persulfate solution, and combinations of these.

Furthermore, as shown in FIG. 2B(k), if necessary, metal plating layers (13, 13′) such as tin plating or the like may be formed on at least a part of the copper wiring of the double-sided copper wiring polyimide film 113, whereby a double-sided copper wiring polyimide film 114 subjected to metal plating is obtained.

### Embodiment 3

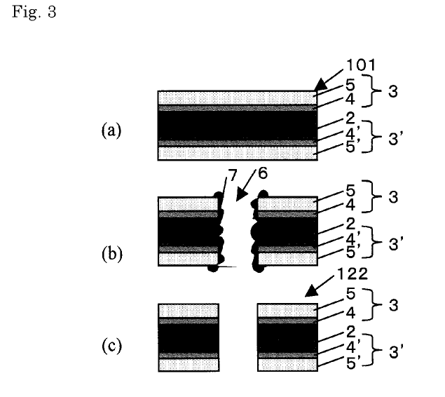

In this Embodiment, one example of the method of forming a via hole in a via hole-forming processing in Embodiments 1 and 2 is illustrated in FIG. 3.

As shown in FIG. 3(a), there is provided a polyimide film 101 laminated with sheets of copper foil with carrier on both sides thereof. This double-sided copper foil laminated polyimide film with carrier 101 contains a copper foil with carrier 3, a polyimide film 2 and a copper foil with carrier 3′ laminated in this order, wherein each copper foil with carrier (3, 3′) is respectively a laminate of each copper foil (4, 4′) and carrier foil (5, 5′) as the protection layer. Herein, the thickness of the copper foil is in the range of 1 to 8 μm and preferably in the range of 1 to 6 μm.

In the next step, as shown in FIG. 3(b), a via hole 6 is formed on a portion of the double-sided copper foil laminated polyimide film with carrier 101, through the copper foil with carrier 3 and 3′ on both sides and a polyimide film 2 by using a laser or the like. A plurality of via holes may be formed. As shown in FIG. 3(b), the via hole 6 may be formed as a through hole penetrating the copper foil with carrier 3′ including the carrier foil 5′ on the back side, or as a hole reaching the carrier foil 5′ by removing the copper foil 4′ on the back side (to be a through hole after peeling off the carrier foil 5′), or as a hole obtained by removing up to the polyimide film but leaving the copper foil 4′ on the back side. Various shapes can be formed.

In the subsequent steps, the same process is employed as in the steps of FIG. 1A(c) of Embodiment 1 or FIG. 2A(c) of Embodiment 2.

In the aforementioned steps of Embodiments 1 to 3, roll-to-roll process may be used for continuous operation.

### Embodiment 4

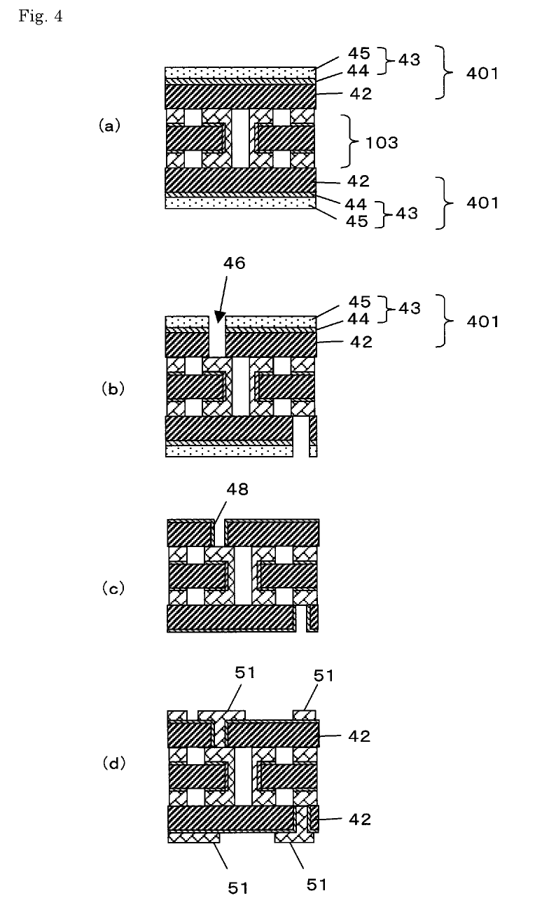

The aforementioned processes of Embodiments 1 to 3 can be applied to a laminated board having 3 or more layers. For example, there is provided a double-sided wiring pattern-formed substrate (e.g., FIG. 1B(k)) according to the production process of the first part of Embodiment 1. As shown in FIG. 4(a), laminates 401 each comprising a copper foil with carrier 43 (copper foil 44 and carrier foil 45) laminated on one side of the polyimide film 42 are laminated through bonding sheets (not illustrated) on both sides of the double-sided copper wiring polyimide film 103 such that the copper foil with carrier is the top surface layer.

Next, a via hole 46 is formed by laser processing in the same manner as in Embodiment 1, and then subjected to the wet blast treatment (FIG. 4(b)). Subsequently, the carrier foils 45 are peeled off, half etching is performed and then a conductive film 48 is formed on the polyimide surface of the via hole 46 (FIG. 4(c)). Thereafter, formation of a resist pattern, electrolytic copper-plating, removal of the resist pattern layer, flash etching, as necessary metal plating and the like are carried out in the similar manner to Embodiment 1, whereby, as shown in FIG. 4(d), copper plating layers 51 for electrically connecting with the inner-level wiring through the via hole are formed. According to such a production method, it is possible to produce a multi-layer copper wiring polyimide film substrate having a via hole between respective layers.

The details of aforementioned production process can be determined in the similar manner to Embodiment 1. Furthermore, although the multi-layer wiring is formed by a semi-additive method herein, it may be formed by a subtractive method as described in Embodiment 2, or depending on the situation, the semi-additive method and subtractive method may be used separately in the steps of forming different layers.

Furthermore, in place of the laminate 401 comprising the polyimide film 42 and the copper foil with carrier 43, a copper foil with carrier with resin having copper foil with carrier laminated on a bonding sheet is used and is laminated on the double-sided wiring pattern-formed substrate (e.g., FIG. 1B(k)) such that the copper foil with carrier is the top surface layer, whereby it is possible to produce a multi-layer wiring polyimide film substrate in the same manner.

### Embodiment 5

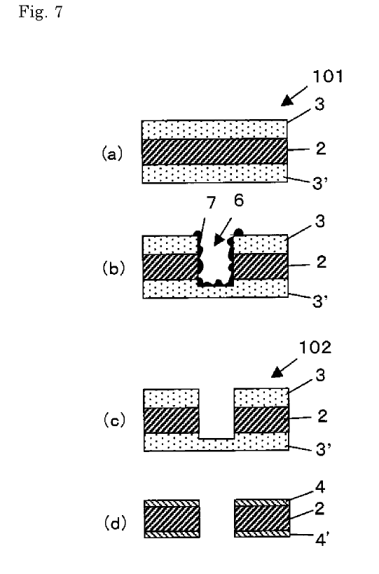

In this Embodiment, in place of the copper foil with carrier in the aforementioned processes of Embodiments 1, 2 and 4, there is used a copper foil including a carrier foil to be the protection layer and an inner metal layer portion both of which are present as a single layer that cannot be distinguished from each other, and an example of the method using a double-sided copper foil laminated polyimide film obtained by removing the protection layer portion by etching is illustrated in FIG. 7.

As shown in FIG. 7(a), there is provided a polyimide film 101 laminated with sheets of copper foil on both sides thereof. In this double-sided copper foil laminated polyimide film 101, a copper foil 3, a polyimide film 2 and a copper foil 3′ are laminated in this order.

In the next step, as shown in FIG. 7(b), a via hole 6 is formed on a prescribed place of the double-sided copper foil laminated polyimide film 101, through the copper foil 3 on one side, the polyimide film 2 and the copper foil 3′ by using a laser. A plurality of via holes may be formed. As shown in FIG. 7(b), the via hole 6 may be formed as a hole obtained by removing up to a part of the copper foil 3′ on the back side so as to be a through hole finally or a through hole penetrating the copper foil 3′ completely, or as a hole obtained by removing up to the polyimide film but leaving the copper foil 3′ on the back side. Various shapes can be formed.

After forming the via hole(s), particularly after forming the via hole(s) by laser processing, as shown in FIG. 7(b), resin smear and resin burr, and metal smear and metal burr 7 appear inside the via hole 6 and at the periphery of the via hole on the surface of the copper foil 3. In the next step, the inside and the periphery of the via hole are cleaned by the wet blast treatment. The wet blast treatment can be performed in accordance with a well-known method, for example, a method described in Japanese Laid-open Patent Publication No. 2003-318519 (Patent Document 1). A double-sided copper foil laminated polyimide film 102 after performing cleaning by the wet blast treatment is illustrated in FIG. 7(c).

In the next step, as shown in FIG. 7(d), from the double-sided copper foil laminated polyimide film 102, the surface portion of the copper foil, which is the protection layer portion, is removed by etching, while portion of the copper foil to be the inner metal layer portion remains. Specifically, the thickness of the protection layer portion, which also depends on the materials, is usually not less than 2 μm, preferably not less than 4 μm and further preferably not less than 6 μm in order to remove the portion with large stress applied by blast processing. Further, when the protection layer portion is excessively thick, it takes time for removing the protection layer and it is hard to control the thickness of the remaining inner metal layer portion. So, it is preferable that the thickness is not excessively thick, and it is, for example, not more than 100 μm, preferably not more than 50 μm and more preferably not more than 20 μm.

Moreover, the thickness of the inner metal layer portion to be remained after removing the protection layer portion is from 0.5 to 16 μm, preferably from 0.5 to 8 μm and further preferably from 0.5 to 5 μm. The thickness of the inner metal layer portion may be properly selected according to a method for forming a circuit. However, when a protection layer is not provided, the thinner metal layer portion result in larger extension and further the stress reaches up to the insulating resin layer. Therefore, if the remaining metal layer portion is thinner, the effect of the protection layer is remarkable. For example, when a circuit is formed by means of a semi-additive method of Embodiment 1, the thickness may be thinned to the range of 0.5 to 2 μm. When a circuit is formed by means of a subtractive method of Embodiment 2, it is further effective when it is thinned to the range of 2 to 8 μm and preferably to the range of 2 to 5 μm.

For etching of the copper foils, a well-known method may be appropriately selected and carried out. For example, there may be used a method of removing the copper foils to be the protection layer portions such as a method of dipping the copper foil laminated polyimide film in a well-known etching solution or a method of spraying an etching solution on the film using a spraying apparatus. As the etching solution, the well-known ones can be used, and examples thereof include an aqueous ferric sulfate solution, an aqueous ferric chloride solution, a solution in which hydrogen peroxide is mixed with sulfuric acid, and a solution containing an aqueous sodium persulfate solution as a main ingredient. Examples thereof include DP-200 manufactured by Ebara-Udylite Co., Ltd. and ADEKA TEC CAP manufactured by Asahi Denka Kogyo K.K.

As a result, there is obtained a double-sided copper foil laminated polyimide film in which the copper foil 4 to be the inner metal layer portion, the polyimide film 2 and the copper foil 4′ to be the inner metal layer portion are laminated.

The subsequent steps can be determined in the similar manner to the steps after peeling off the carrier foils in Embodiments 1 and 2. However, in this Embodiment, since the thickness can be thinned to a necessary film thickness by the aforementioned etching, generally, the half etching (FIG. 1A(e)) that is optionally carried out in Embodiment 1 may not be carried out. Further, when applied to a laminated substrate having 3 or more layers, a multi-layer wiring polyimide film substrate can be produced in the similar manner to Embodiment 4.

In the production method of the present invention (typically the aforementioned Embodiments 1 to 5), a through hole or a blind via hole can be formed, for example, by removing through a portion of the copper foil(s) of either one side or both sides and the polyimide film at the same time using a UV-YAG laser, before peeling off the carrier foils on both sides (Embodiments 1 to 4) or before thinning the copper foils (Embodiment 5). Alternatively, the copper foil on the portion of the polyimide film to be holed is removed beforehand by etching or the like, and then the polyimide film may be removed by an irradiation with a carbon dioxide laser to form a blind via hole, or a via hole penetrating both sides may be formed by punching or drilling.

As shown in FIG. 1B(i) of the aforementioned Embodiment 1, when a wiring part is formed by the pattern plating method, the formation of a via hole, by electrically connecting through the hole using an electrolytic-plating method, is preferably carried out at the same time.

In this step of forming a conductive film as shown in FIG. 1A(f) of the aforementioned Embodiment 1 and FIG. 2A(e) of Embodiment 2, the conductive film is formed inside of the through hole or the blind via hole by the so-called DPS (Direct Plating System) method of forming a palladium-tin film by using a palladium-tin colloid catalyst.

Herein, the RISERTRON DPS system manufactured by Ebara-Udylite Co., Ltd. can be exemplified as the DPS step. Herein, a surface treatment with an aqueous solution comprising monoethanolamine as a main agent makes a condition in which the palladium-tin colloid catalyst readily adsorbs. Subsequently, the surface of the thin copper foil having readily-adsorbing property by treatment is removed with a soft etching solution to inhibit formation of a palladium-tin film on the copper foil surface, and ensure adhesion strength of the copper foil surface and electrolytic plating. It is dipped into sodium chloride, hydrochloric acid and so on. After these steps, a Pd—Sn film is formed in the activating step comprising dipping into a palladium-tin colloid liquid. A reducing agent may be added to an alkaline accelerator bath used for activation during final activation in an alkaline accelerator bath containing sodium carbonate, potassium carbonate and copper ion, and an acid accelerator bath containing sulfuric acid. Examples of the reducing agent which can be added include, for example, aldehydes such as formaldehyde, acetaldehyde, propionaldehyde and benzaldehyde, and catechol, resorcin, ascorbic acid and so on. The alkaline accelerator bath to which the reducing agent is added preferably comprises sodium carbonate, potassium carbonate and copper ion. By the method already described, a low resistant film composed of Pd—Sn can be obtained.

A specific example of the method to form a circuit by a semi-additive method using the double-sided copper foil laminated polyimide film with carrier in which the copper foil with carrier is laminated on the both surfaces of polyimide film is illustrated. From a rolled-up double-sided copper foil laminated polyimide film with carrier, a 10.5×25 cm rectangular sample is cut out. The electrolytic copper foil with carrier on both side of the film and the polyimide layer are subjected to laser processing with a UV-YAG LASER [a product of Electro Scientific Industries, Inc. (ESI, Inc.), Model: 5320, Wavelength: 355 μm] to form a through-hole for forming a through-hole via. Subsequently, the via hole is subjected to the wet blast treatment at an air pressure of 0.2 MPa by means of a wet blasting apparatus (a product of Macoho Co., Ltd.) using a mixture of alumina particles and water (alumina concentration: 16 volume %) as an abrasive, and removal of burr and cleaning of the inside of the hole are carried out at the same time. Thereafter, the carrier foils on both sides are peeled off. Using DP-200 manufactured by Ebara-Udylite Co., Ltd. as a half etching solution, the copper foil is dipped at 25° C. for 2 minutes so that the thickness of the copper foil becomes 1 μm. Then a conductive film is formed by the RISERTRON DPS process of Ebara-Udylite Co., Ltd. A dry film-type negative type photoresist (SPG-152, a product of Asahi Kasei Co., Ltd.) is laminated on the DPS-treated copper foil by a heat roll at 110° C., and then the photoresist is exposed to light except a portion where a circuit is intended to be formed (wiring pattern) and the portion to be the through-hole, and unexposed resist is spray-developed with 1% sodium carbonate aqueous solution and removed at 30° C. for 20 seconds. After degreasing and acid-washing the exposed site of the thin copper foil and inside the through-hole in which a conductive film is formed, electrolytic copper plating is conducted in a copper sulfate plating bath with the thin copper foil as a cathode electrode at a current density of 2 A/dm² at 25° C. for 30 minutes, and pattern plating of copper plating with 10 μm in thickness inside the conductive film-formed through-hole is carried out. Subsequently, when the resist layer is removed off by spray treatment with 2% sodium hydroxide aqueous solution at 42° C. for 15 seconds, and then the thin-film copper in an unnecessary portion is removed by spray treatment with a flash etching solution (AD-305E, a product of Asahi Denka Kogyo K.K.) at 30° C. for 30 seconds, a polyimide film having a 30 μm-pitch copper wiring on its both surfaces is obtained.

A specific example of the method to form a circuit by a subtractive method using the double-sided copper foil laminated polyimide film with carrier in which the copper foil with carrier is laminated on the both surfaces of polyimide film is illustrated. From a rolled-up double-sided copper foil laminated polyimide film with carrier, a 10.5×25 cm rectangular sample is cut out. The electrolytic copper foil with carrier on one side of the film and the polyimide layer are subjected to laser processing with a UV-YAG LASER [a product of Electro Scientific Industries, Inc. (ESI, Inc.), Model: 5320, Wavelength: 355 μm] to form a via hole for forming a blind via hole. Subsequently, the via hole is subjected to the wet blast treatment at an air pressure of 0.2 MPa by means of a wet blasting apparatus (a product of Macoho Co., Ltd.) using a mixture of alumina particles and water (alumina concentration: 16 volume %) as an abrasive, and removal of burr and cleaning of the inside of the hole are carried out at the same time. Thereafter, the carrier foils on both sides are peeled off. Then a conductive film is formed by the RISERTRON DPS process of Ebara-Udylite Co., Ltd. After degreasing and acid-washing the copper foil and inside the via-hole in which a conductive film is formed, electrolytic copper plating is conducted in a copper sulfate plating bath with the thin copper foil as a cathode electrode at a current density of 2 A/dm² at 25° C. for 30 minutes, and copper plating with 10 μm in thickness inside the conductive film-formed through-hole is carried out. A dry film-type negative type photoresist (SPG-152, a product of Asahi Kasei Co., Ltd.) is laminated on the copper-plating treated copper foil by a heat roll at 110° C., and then the photoresist is exposed to light on a portion where a circuit is intended to be formed (wiring pattern) and the portion to be the through-hole, and unexposed resist is spray-developed with 1% sodium carbonate aqueous solution and removed at 30° C. for 20 seconds. Subsequently, spray etching is performed with an aqueous ferric chloride solution at 50° C. for 10 seconds, then, the resist layer is removed by performing a spray treatment with an aqueous solution of 2% sodium hydroxide at 42° C. for 15 seconds, thereby a polyimide film having 60 μm-pitch copper wirings on both sides thereof is obtained.

For the copper wiring polyimide film, metal plating such as tin plating or the like can be further carried out on at least a part of the copper wiring.

Next, the double-sided copper foil laminated polyimide film with carrier to be used in the present invention will be described below. In the copper foil laminated polyimide film with carrier, as described above, sheets of copper foil with carrier are directly laminated on both sides of the polyimide film, wherein the copper foil has a thickness in the range of 1 to 8 μm.

In the copper foil with carrier, the thickness of the carrier is not particularly limited, but it may be selected such that the thin copper foil can be reinforced; and the thickness of the carrier is preferably from 10 to 40 μm, further preferably from 10 to 35 μm and more preferably from 10 to 18 μm. The thickness of the copper foil 4 is preferably from 1 to 8 μm, further preferably from 1 to 6 μm, more preferably from 2 to 5 μm and more preferably from 2 to 4 μm, while the surface roughness Rz of the copper foil in the side laminated to polyimide film is preferably 1.0 μm or less, further preferably 0.8 μm or less and more preferably 0.7 μm or less.

It is possible to obtain a wiring substrate having excellent adhesion strength even after heating at 150° C. for 168 hours, by using the laminate of the copper foil with carrier 3 and polyimide, in particular preferably a multi-layer polyimide, which is obtained by laminating and integrating a thermo-compression bonding polyimide film on one side or both sides of a high heat resistant aromatic polyimide layer.

As the copper foil of the copper foil with carrier, there can be used copper, copper alloy and the like, such as electrolytic copper foil, rolled copper foil or the like.

The material of the carrier of the copper foil with carrier is not particularly limited, but it may be selected so that it can be attached to the copper foil, function so as to reinforce and protect the copper foil, be readily peeled off from the copper foil and withstand a lamination temperature for laminating polyimide. For example, aluminum foil, copper foil, resin foil with metal-coated surface and the like can be used.

In the case of the electrolytic copper foil with carrier foil, since copper components are electrodeposited on the carrier foil surface to form an electrolytic copper foil, the carrier foil needs to have at least conductivity.

The carrier foil that can be used is those that travel through a series of manufacturing steps, and keep juncture with the copper foil layer at least until completion of producing the copper foil laminated polyimide film, and facilitate handling.

The carrier foil, which may be used, is removed by peeling off the carrier foil after laminating the copper foil with carrier foil to the polyimide foil, or can be removed by an etching method after laminating the copper foil with a carrier foil to the polyimide film.

In the copper foil with carrier, those obtained by bonding the carrier and the copper foil by an adhesive agent of a metal or ceramic can be suitably used as they are excellent in heat resistance.

For the copper foil with carrier, at least one side to be laminated with the polyimide film is surface-treated, such as roughening treatment, anti-corrosion treatment, heat resistant treatment, chemical resistant treatment or the like, with at least one metal selected from Ni, Cr, Co, Zn, Sn and Mo or an alloy comprising at least one of these metals. Furthermore, the surface can be silane-coupling treated.

The polyimide film of the copper foil laminated polyimide film with carrier 1 can be directly laminated with the copper foil of the copper foil with carrier, and examples thereof include a polyimide film used as a base material of electronic parts such as printed wiring boards, flexible printed circuit boards, TAB tapes, COF substrates and the like; and polyimides obtained from acid components and diamine components constituting these polyimide film, or polyimides comprising acid components and diamine components constituting these polyimide film.

As the polyimide film 2, its linear expansion coefficient (50 to 200° C.) is preferably close to the linear expansion coefficient of the copper foil to be laminated with the polyimide film, and the linear expansion coefficient (50 to 200° C.) of the polyimide film is preferably from 0.5×10⁻⁵ to 2.8×10⁻⁵ cm/cm/° C.

As the polyimide film, that having heat shrinkage ratio of not more than 0.05% is preferably used due to small heat distortion.

The polyimide film can be used in the form of a mono-layer film, a multi-layer film laminated with two or more layers and a sheet.

The thickness of the polyimide film is not particularly limited, but preferably it may be in the range such that lamination of the polyimide film and the copper foil with carrier can be done without any problem, manufacturing and handling can be done, and the copper foil can be sufficiently supported. It is preferably from 1 to 500 μm, more preferably from 2 to 300 μm, further preferably from 5 to 200 μm, more preferably from 7 to 175 μm, and particularly preferably 8 to 100 μm.

As the polyimide film, substrates surface may be treated by such as corona discharge treatment, plasma treatment, chemical roughening treatment, physical roughening treatment and the like at least on one side of the substrate.

For the polyimide film of the copper foil laminated polyimide film with carrier, there can be used a multi-layer polyimide film having at least two or more layers comprising a thermo-compression bonding polyimide layer (a) which can be directly laminated with the copper foil, on one side or both sides of a heat resistant polyimide layer (b) by compression or thermo-compression.

Furthermore, for the copper foil laminated polyimide film with carrier, there can be used those obtained by laminating the heat resistant polyimide layer (b) and the copper foil with carrier, through the thermo-compression bonding polyimide layer (a), by compression or thermo-compression.

Specific examples of the heat resistant polyimide layer (b) and the polyimide film include polyimide films such as product name: Upilex (S or R) (a product of Ube Industries, Ltd.), product name: Kapton (a product of DuPont-TORAY Co., Ltd.), product name: Apical (a product of Kaneka Corp.) and the like; or polyimide obtained from acid components and diamine components constituting these films.

The polyimide film can be produced by a well-known method, and for example, for a mono-layer polyimide film, the following methods can be utilized:

(1) a method involving flow-casting or applying a solution of a poly(amic acid) as a polyimide precursor on a support, and imidizing it; and

(2) a method involving flow-casting or applying a polyimide solution on a support, and then, if necessary, heating it.

A two or more-layer polyimide film can be obtained by the following methods:

(3) a method involving flow-casting or applying a solution of a poly(amic acid) as a polyimide precursor on a support, and furthermore flow-casting or applying successively a solution of a poly(amic acid) as a polyimide precursor for the second or later layers on the upper surface of the previous poly(amic acid) layer flow-casted or applied on the support, and imidizing them;

(4) a method involving simultaneously flow-casting or applying solutions of a poly(amic acid) for two or more layers as a polyimide precursor on a support, and imidizing them;

(5) a method involving flow-casting or applying a polyimide solution on a support, and furthermore successively flow-casting or applying a polyimide solution for the second or later layers on the upper surface of the previous polyimide film flow-casted or applied on the support, and, if necessary, heating them;

(6) a method involving simultaneously flow-casting or applying polyimide solutions for two or more layers on a support, and, if necessary, heating them; and

(7) a method involving laminating two or more polyimide films obtained by the above methods (1) to (6) directly or through an adhesive agent.

When the copper foil with carrier and the polyimide film are laminated, a heating machine, a compression machine or a thermo-compression machine may be used, and preferably a heating or compression condition is appropriately selected depending on materials to be used. Although the production process is not particularly limited as long as continuous or batch laminating is employable, it is preferably carried out continuously by using a roll laminator, a double-belt press or the like.

As an example of the production method of the copper foil laminated polyimide film with carrier, the following method is exemplified. That is, a lengthy copper foil with carrier (length of 200 to 2,000 m), a lengthy polyimide film and a lengthy copper foil with carrier are piled in three layers in this order. They are preferably pre-heated at about 150 to 250° C., particularly at a temperature higher than 150° C. and 250° C. or lower for about 2 to 120 seconds in line immediately before introducing in the machine by using a pre-heater such as a hot-air blower or an infrared heating machine. By using a pair of compression-bonding rolls or a double-belt press, the three-ply of copper foil with carrier/polyimide film/copper foil with carrier is thermally bonded under pressure, wherein a temperature in a heating and compression-bonding zone of the compression-bonding rolls or the double-belt press is within a range of higher by 20° C. or more than a glass transition temperature of polyimide and below 400° C., particularly higher by 30° C. or more than the glass transition temperature and below 400° C. In particular, in the case of a double-belt press, the laminate is successively cooled while being pressed in a cooling zone. The laminate is suitably cooled to a temperature lower by 20° C. or more, particularly lower by 30° C. or more than the glass transition temperature of the polyimide to complete lamination, and rewound in a roll form. Thus, the roll-form one-sided or double-sided copper foil laminated polyimide film with carrier can be produced.

The pre-heating of the polyimide film before thermo-compression bonding is effective to prevent the occurrence of defective appearance by laminate's foaming after thermo-compression bonding or foaming when soaking in a solder bath during formation of electronic circuits due to moisture contained in the polyimide. Thus, decreasing in production yield can be prevented.

The double-belt press can perform heating to high temperature and cooling down while applying pressure, and a hydrostatic type one using a heat carrier is preferable.

In the production of the double-sided copper foil laminated polyimide film with carrier foil, lamination is carried out preferably at a drawing rate of 1 m/min or more by thermo-compression bonding and cooling under pressure using a double-belt press. Thus-obtained double-sided copper foil laminated polyimide film with carrier is continuously long and has a width of about 400 mm or more, particularly about 500 mm or more, and high adhesion strength (the peel strength of the metal foil and the polyimide film is not less than 0.7 N/mm, and the retention rate of the peel strength is not less than 90% after heating treatment at 150° C. for 168 hours), and further has good appearance so that substantially no wrinkles are observed on the copper foil surface. Thus, the double-sided copper foil laminated polyimide film with carrier can be obtained.

In order to mass-produce the double-sided copper foil laminated polyimide film with carrier with good appearance, while one or more combinations of the thermo-compression bonding polyimide film and the copper foil with carrier are being supplied, protectors are placed between top-surface layer at both sides and the belts (i.e., two sheets of protectors), and these together are preferably bonded and laminated by thermo-compression bonding and cooling under pressure.

For the protector, its material is not particularly limited for use as long as it is non-thermo-compression bonding and has a good surface smoothness, and the preferred examples thereof include metal foil, particularly copper foil, stainless foil, aluminum foil, and high heat resistant polyimide film (Upilex S, manufactured by Ube Industries, Ltd., Kapton H manufactured by DuPont-TORAY Co., Ltd.) and the like having about 5 to 125 μm in thickness.

In the thermo-compression bonding polyimide film, as the heat resistant polyimide layer (b), it is preferable to use a heat resistant polyimide constituting a base film which can be used as a tape material of electronic parts such as printed wiring boards, flexible printed circuit boards, TAB tapes, COF substrates and the like.

In the thermo-compression bonding polyimide film, the heat resistant polyimide used for the heat resistant polyimide layer (layer b) may be selected from those having at least one of the following properties, or those having at least two of the following properties {i.e., the combination of 1) and 2), 1) and 3) or 2) and 3)}, and particularly from those having all of the following properties:

1) in the case of polyimide film alone, a glass transition temperature is 300° C. or higher, preferably 330° C. or higher, and further preferably, a glass transition temperature is undetectable;

2) in the case of polyimide film alone, a linear expansion coefficient (50 to 200° C.) (MD) is preferably close to a thermal expansion coefficient of a metal foil such as a copper foil laminated on a heat resistant resin substrate, and when using a copper foil as a metal foil, a thermal expansion coefficient of the heat resistant resin substrate is preferably from 5×10⁻⁶ to 28×10⁻⁶ cm/cm/° C., more preferably from 9×10⁻⁶ to 20×10⁶ cm/cm/° C. and further preferably from 12×10⁻⁶ to 18×10⁻⁶ cm/cm/° C.; and

3) in the case of polyimide film alone, a tensile modulus (MD, ASTM-D882) is 300 kg/mm² or more, preferably 500 kg/mm² or more and further preferably 700 kg/mm² or more.

As the heat resistant polyimide of the heat resistant polyimide layer (b), there can be used polyimide obtained from the combination of:

(1) an acid component containing at least one selected from 3,3′,4,4′-biphenyltetracarboxylic dianhydride, pyromellitic dianhydride and 1,4-hydroquinone dibenzoate-3,3′,4,4′-tetracarboxylic dianhydride, and preferably an acid component containing these acid components in an amount of at least not less than 70 mole %, further preferably not less than 80 mole % and more preferably not less than 90 mole %; and

(2) diamine component containing at least one selected from p-phenylene diamine, 4,4′-diaminodiphenyl ether, m-tolidine and 4,4′-diamino benzanilide, and preferably a diamine component containing these diamine components in an amount of at least not less than 70 mole %, further preferably not less than 80 mole % and more preferably not less than 90 mole %.

As the combination of the acid component and the diamine component constituting the heat resistant polyimide layer (b), there can be exemplified those obtained by containing the following combinations:

1) 3,3′,4,4′-biphenyltetracarboxylic dianhydride, and p-phenylene diamine or (p-phenylene diamine and 4,4-diaminodiphenyl ether),

2) 3,3′,4,4′-biphenyltetracarboxylic dianhydride and pyromellitic dianhydride, and p-phenylene diamine or (p-phenylene diamine and 4,4-diaminodiphenyl ether),

3) pyromellitic dianhydride, and p-phenylene diamine and 4,4-diaminodiphenyl ether, and

4) 3,3′,4,4′-biphenyltetracarboxylic dianhydride and p-phenylene diamine, as main ingredient components (not less than 50 mole % in the total 100 mole %). They are used as materials of electronic parts such as printed wiring boards, flexible printed circuit boards, TAB tapes and the like, and they are preferred because they have excellent mechanical properties over a wide temperature range, long-term heat resistance, excellent resistance to hydrolysis, a high heat decomposition initiation temperature, small heat shrinkage ratio and linear expansion coefficient, and excellent flame retardancy.

As the acid component capable of obtaining heat resistant polyimide of the heat resistant polyimide layer (b), there can be used an acid dianhydride component such as 2,3,3′,4′-biphenyltetracarboxylic dianhydride, 3,3′,4,4′-benzophenonetetracarboxylic dianhydride, bis(3,4-dicarboxyphenyl)ether dianhydride, bis(3,4-dicarboxyphenyl)sulfide dianhydride, bis(3,4-dicarboxyphenyl)sulfone dianhydride, bis(3,4-dicarboxyphenyl)methane dianhydride, 2,2-bis(3,4-dicarboxyphenyl)propane dianhydride, 2,2-bis(3,4-dicarboxyphenyl)-1,1,1,3,3,3-hexafluoropropane dianhydride, 2,2-bis[(3,4-dicarboxyphenoxy)phenyl]propane dianhydride or the like, in addition to the acid components illustrated above, in the ranges in which the characteristics of the present invention are not impaired.

As the diamine component capable of obtaining heat resistant polyimide of the heat resistant polyimide layer (b), there can be used a diamine component such as m-phenylene diamine, 3,4′-diaminodiphenyl ether, 3,3′-diaminodiphenyl sulfide, 3,4′-diaminodiphenyl sulfide, 4,4′-diaminodiphenyl sulfide, 3,3′-diaminodiphenyl sulfone, 3,4′-diaminodiphenyl sulfone, 4,4′-diaminodiphenyl sulfone, 3,3′-diaminobenzophenone, 4,4′-diaminobenzophenone, 3,4′-diaminobenzophenone, 3,3′-diaminodiphenyl methane, 4,4′-diaminodiphenyl methane, 3,4′-diaminodiphenyl methane, 2,2-di(3-aminophenyl)propane, 2,2-di(4-aminophenyl)propane and the like, in addition to the diamine components illustrated above, in the ranges in which the characteristics of the present invention are not impaired.

As the thermo-compression bonding polyimide layer (layer a), there can be used known polyimide having a property capable of hest-seal bonding (thermo-compression bonding property) a tape material of electronic parts such as printed wiring boards, flexible printed circuit boards, TAB tapes, COF substrates and the like or the heat resistant polyimide and the copper foil, or having a property capable of performing hest-seal bonding under pressure (thermo-compression bonding property).

The thermo-compression bonding polyimide for the thermo-compression bonding polyimide layer (layer a) is preferably polyimide having thermo-compression bonding property capable of performing lamination with a copper foil at a temperature in the range from a glass transition temperature of the thermo-compression bonding polyimide to 400° C.

As the thermo-compression bonding polyimide of the thermo-compression bonding polyimide layer (layer a) for the thermo-compression bonding polyimide film, there can be used those having at least one property below, those having at least two properties below {i.e., the combination of 1) and 2); 1) and 3); or 2) and 3)}, those having at least three properties below {i.e., the combination of 1), 2) and 3); 1), 3) and 4); 2), 3) and 4); 1), 2) and 4); or the like}, and particularly those having all properties below:

1) the thermo-compression bonding polyimide layer (layer a) has a peel strength between the copper foil and “layer a”, or the copper foil and the thermo-compression bonding polyimide film of 0.7 N/mm or more, and the retention ratio of a peel strength after heat treatment at 150° C. for 168 hours is 90% or more, further 95% or more and particularly 100% or more;

2) its glass transition temperature is from 130 to 330° C.;

3) its tensile modulus is from 100 to 700 Kg/mm²; and

4) its linear expansion coefficient (50 to 200° C.) (MD) is from 13×10⁻⁶ to 30×10⁻⁶ cm/cm/° C.

As a thermo-compression bonding polyimide of the thermo-compression bonding polyimide layer (layer a), there can be used polyimide obtained from:

(1) an acid component containing at least one component selected from acid dianhydrides such as 3,3′,4,4′-biphenyltetracarboxylic dianhydride, 2, 3,3′, 4′-biphenyltetracarboxylic dianhydride, pyromellitic dianhydride, 3,3′,4,4′-benzophenonetetracarboxylic dianhydride, bis(3,4-dicarboxyphenyl)ether dianhydride, bis(3,4-dicarboxyphenyl) sulfide dianhydride, bis(3,4-dicarboxyphenyl)sulfone dianhydride, bis(3,4-dicarboxyphenyl)methane dianhydride, 2,2-bis(3,4-dicarboxyphenyl)propane dianhydride, 1,4-hydroquinone dibenzoate-3,3′,4,4′-tetracarboxylic dianhydride and the like, and preferably an acid component containing these acid components in an amount of at least not less than 70 mole %, further preferably not less than 80 mole % and more preferably not less than 90 mole %, and

(2) a diamine component containing at least one component selected from diamines such as 1,3-bis(4-aminophenoxy)benzene, 1,3-bis(3-aminophenoxy)benzene, 1,4-bis(4-aminophenoxy)benzene, 3,3′-diaminobenzophenone, 4,4′-bis(3-aminophenoxy)biphenyl, 4,4′-bis(4-aminophenoxy)biphenyl, bis[4-(3-aminophenoxy)phenyl]ketone, bis[4-(4-aminophenoxy)phenyl]ketone, bis[4-(3-aminophenoxy)phenyl]sulfide, bis[4-(4-aminophenoxy)phenyl]sulfide, bis[4-(3-aminophenoxy)phenyl]sulfone, bis[4-(4-aminophenoxy)phenyl]sulfone, bis[4-(3-aminophenoxy)phenyl]ether, bis[4-(4-aminophenoxy)phenyl]ether, 2,2-bis[4-(3-aminophenoxy)phenyl]propane, 2,2-bis[4-(4-aminophenoxy)phenyl]propane and the like as a diamine component, and preferably a diamine component containing these diamine components in an amount of at least not less than 70 mole %, further preferably not less than 80 mole % and more preferably not less than 90 mole %.

As the combination of the acid component and the diamine component capable of obtaining polyimide of the thermo-compression bonding polyimide layer (layer a), there can be used polyimide obtained from:

(1) an acid component containing at least one component selected from acid dianhydrides such as 3,3′,4,4′-biphenyltetracarboxylic dianhydride and 2,3,3′,4′-biphenyltetracarboxylic dianhydride, and preferably an acid component containing these acid components in an amount of at least not less than 70 mole %, further preferably not less than 80 mole % and more preferably not less than 90 mole %; and

(2) a diamine component containing at least one component selected from diamines such as 1,3-bis(4-aminophenoxy)benzene, 1,3-bis(3-aminophenoxy)benzene, 4,4′-bis(3-aminophenoxy)biphenyl, bis[4-(3-aminophenoxy)phenyl]sulfone, bis[4-(3-aminophenoxy)phenyl]ether, 2,2-bis[4-(3-aminophenoxy)phenyl]propane, 2,2-bis[4-(4-aminophenoxy)phenyl]propane and the like as a diamine component, and preferably a diamine component containing these diamine components in an amount of at least not less than 70 mole %, further preferably not less than 80 mole % and more preferably not less than 90 mole %.

As the diamine component capable of obtaining polyimide of the thermo-compression bonding polyimide layer (layer a), there can be used a diamine component such as m-phenylene diamine, 3,4′-diaminodiphenyl ether, 3,3′-diaminodiphenyl sulfide, 3,4′-diaminodiphenyl sulfide, 4,4′-diaminodiphenyl sulfide, 3,3′-diaminodiphenyl sulfone, 3,4′-diaminodiphenyl sulfone, 4,4′-diaminodiphenyl sulfone, 3,3′-diaminobenzophenone, 4,4′-diaminobenzophenone, 3,4′-diaminobenzophenone, 3,3′-diaminodiphenyl methane, 4,4′-diaminodiphenyl methane, 3,4′-diaminodiphenyl methane, 2,2-di(3-aminophenyl)propane, 2,2-di(4-aminophenyl)propane and the like, in addition to the diamine components illustrated above, in the ranges in which the characteristics of the present invention are not impaired.

Both of the polyimide of the heat resistant polyimide layer (layer b) and the polyimide of the thermo-compression bonding polyimide layer (layer a) can be synthesized by a known method such as random polymerization or block polymerization, or the method including combining a plurality of polyimide precursor solutions or polyimide solutions synthesized beforehand, mixing the plurality of solutions and then mixing under reaction conditions to give a uniform solution.

Both of the polyimide of the heat resistant polyimide layer (layer b) and the polyimide of the thermo-compression bonding polyimide layer (layer a) can be produced by a method in which acid components and diamine components are reacted in an organic solvent at a temperature of about not more than 100° C., further not more than 80° C. and further 0 to 60° C., particularly at a temperature of from 20 to 60° C., for about 0.2 to 60 hours to give a polyimide precursor solution, and then using this polyimide precursor solution as a dope liquid, a thin film of the dope liquid is formed, and its solvent is evaporated and removed from the thin film and at the same time the polyimide precursor is imidized.

Furthermore, in the case that polyimide excellent in solubility is used, the organic solvent solution of the polyimide can be obtained by heating the polyimide precursor solution at 150 to 250° C., or adding an imidization agent at not more than 150° C., particularly reacting at a temperature of from 15 to 50° C., and followed by evaporating the solvent after imide-cyclizing, or followed by precipitation in a poor solvent to give powder, and dissolving the powder in the organic solution.

When polymerization reaction of the polyimide precursor in solution is carried out, the concentration of the total monomers in an organic polar solvent may be suitably selected depending on the purpose of use or the purpose of production. For example, for the polyimide precursor solution of the heat resistant polyimide layer (layer b), the concentration of the total monomers in the organic polar solvent is preferably from 5 to 40% by mass, further preferably form 6 to 35% by mass and particularly preferably from 10 to 30% by mass. For the polyimide precursor solution of the thermo-compression bonding polyimide layer (layer a), the concentration of the total monomers in the organic polar solvent is preferably from 1 to 15% by mass and particularly from 2 to 8% by mass.

When polymerization reaction of the polyimide precursor solution is carried out, the solution viscosity may be suitably selected depending on the purpose of use (coating, flow casting or the like) or the purpose of production. The solution of a poly(amic acid) (polyimide precursor) preferably has the rotating viscosity, measured at 30° C., from about 0.1 to 5,000 poises, particularly from about 0.5 to 2,000 poises and further preferably from about 1 to 2,000 poises, from the viewpoint of workability of handling this solution of a poly(amic acid). Accordingly, the aforementioned polymerization reaction is preferably carried out to the extent that the generated poly(amic acid) exhibits the above viscosity.

For the thermo-compression bonding polyimide layer (layer a), a polyimide precursor solution may be produced in the above method, and an additional organic solvent may be added for dilution.

For both of the polyimide of the heat resistant polyimide layer (layer b) and the polyimide of the thermo-compression bonding polyimide layer (layer a), the almost-equimolar amounts of diamine components and tetracarboxylic dianhydrides, the amounts thereof with a little excess amount of diamine components or the amounts thereof with a little excess amount of acid components are reacted in an organic solvent so that a polyimide precursor solution (it may be partially imidized as long as uniform solution condition is obtained) can be obtained.

Both of the polyimide of the heat resistant polyimide layer (layer b) and the polyimide of the thermo-compression bonding polyimide layer (layer a) may be synthesized by adding dicarboxylic anhydrides, such as phthalic anhydride and its substituted compound, hexahydrophthalic anhydride and its substituted compound, succinic anhydride and its substituted compound and so on, particularly phthalic anhydride, in order to cap the amine terminal.

For both of the polyimide of the heat resistant polyimide layer (layer b) and the polyimide of the thermo-compression bonding polyimide layer (layer a), the amount of diamines used in an organic solvent (as the number of moles of amino groups) is from 0.95 to 1.05, particularly from 0.98 to 1.02 and particularly from 0.99 to 1.01 based on the total number of moles of acid anhydrides (as the total number of moles of acid anhydride groups of tetra acid dianhydrides and dicarboxylic acid anhydrides). When dicarboxylic acid anhydrides are used, individual components are reacted in such a ratio that the amount of dicarboxylic acid anhydrides as the ratio to the mole of acid anhydride groups of tetra acid dianhydrides is not more than 0.05.

For the purpose to restrict gelation of the polyimide precursor, a phosphorus-base stabilizer, for example, triphenyl phosphite, triphenyl phosphate and so on can be added within a range of 0.01 to 1% of the solid (polymer) concentration during polymerization of the poly(amic acid).

In addition, for the purpose to promote imidization, a basic organic compound may be added to the dope liquid. For example, there may be used imidazole, 2-imidazole, 1, 2-dimethylimidazole, 2-phenylimidazole, benzimidazole, isoquinoline, substituted-pyridine and so on as an imidization promoter in a proportion of 0.05 to 10 weight % and particularly 0.1 to 2 weight % based on the poly(amic acid). Since these compounds can form a polyimide film at a relatively low temperature, they may be used in order to avoid insufficient imidization.

Furthermore, for the purpose to stabilize adhesion strength, organic aluminum compounds, inorganic aluminum compounds or organic tin compounds may be added to the solution of a poly(amic acid), particularly for the thermo-compression bonding polyimide. For example, aluminum hydroxide, aluminum triacetylacetonate and the like may be added at 1 ppm or more and particularly at 1 to 1,000 ppm as an aluminum metal to the poly(amic acid).

As for the organic solvent used for production of the poly(amic acid), there can be exemplified N-methyl-2-pyrrolidone, N,N-dimethylformamide, N,N-dimethylacetamide, N,N-diethylacetamide, dimethylsulfoxide, hexamethylphosphoramide, N-methylcaprolactam, cresols and the like. These organic solvents may be used alone or more than two kinds together.

The polyimide film having thermo-compression bonding property can be obtained preferably by a method (i) or (ii), i.e.:

(i) by the coextrusion-flow-casting film formation method (also being simply referred to as multi-layer extrusion method), the dope liquid of the heat resistant polyimide layer (layer b) and the dope liquid of the thermo-compression bonding polyimide layer (layer a) are laminated, dried and imidized to obtain a multi-layer polyimide film, or

(ii) the dope liquid of the heat resistant polyimide layer (layer b) is flow-cast on a support, and dried to give a self-supporting film (gel film), and next, on one side or both sides thereof, the dope liquid of the thermo-compression bonding polyimide layer (layer a) is applied, dried and imidized to give a multi-layer polyimide film.

For the coextrusion method, there may be used a well-known method, for example, a method described in the Japanese Laid-open Patent Publication No. H03-180343 (Japanese Kokoku Patent Publication No. H07-102661).

An embodiment of the production of a three-layer thermo-compression bonding polyimide film having thermo-compression bonding properties on both sides is illustrated.

The solution of a poly(amic acid) for the heat resistant polyimide layer (layer b) and the solution of a poly(amic acid) for the thermo-compression bonding polyimide layer (layer a) are supplied to a three-layer extrusion molding die by a three-layer coextrusion method so that the thickness of the heat resistant polyimide layer (layer b) is 4 to 45 μm and the thickness of the thermo-compression bonding polyimide layer (layer a) on both sides is 3 to 10 μm in total, and cast on a support and this is flow-cast and applied on a smooth support surface such as a stainless mirror surface and a stainless belt surface, and at 100 to 200° C., the polyimide film A as a self-supporting film can be obtained in a semi-cured state or a dried state before the semi-curing.

For the polyimide film A as a self-supporting film, if a flow-casted film is treated at a temperature higher than 200° C., some defects tend to occur such as decrease in adhesiveness during production of the polyimide film having thermo-compression bonding property. This semi-cured state or the state before the semi-curing means a self-supporting state by heating and/or chemical imidization.

The polyimide film A as a self-supporting film obtained is heated at a temperature of not lower than the glass transition temperature (Tg) of the thermo-compression bonding polyimide layer (layer a) and not higher than degradation-occurring temperature, preferably a temperature of from 250 to 420° C. (surface temperature measured by a surface thermometer) (preferably heating at this temperature for 0.1 to 60 minutes), dried and imidized. Thus, the polyimide film having the thermo-compression bonding polyimide layer (layer a) on both sides of the heat resistant polyimide layer (layer b) is produced.

In the polyimide film A as a self-supporting film obtained, a solvent and generated water remain preferably at about 20 to 60% by mass and particularly preferably from 30 to 50% by mass. This self-supporting film is preferably heated up for relatively short period when it is heated-up to a drying temperature. For example, a heating rate is preferably not less than 10° C./min. When drying, by increasing the tension applied to the self-supporting film, the linear expansion coefficient of the polyimide film A thus finally obtained is reduced.

Then, following the above-mentioned drying step, the self-supporting film is continuously or intermittently dried and heat-treated, in a condition in which at least a pair of side edges of the self-supporting film is fixed by a fixing equipment capable of continuously or intermittently moving together with the self-supporting film, at a high temperature higher than the drying temperature, preferably within a range of 200 to 550° C. and particularly preferably within a range of 300 to 500° C. preferably for 1 to 100 minutes and particularly 1 to 10 minutes. The polyimide film having thermo-compression bonding property on both sides may be formed by sufficiently removing the solvent or the like from the self-supporting film and at the same time sufficiently imidizing the polymer consisting of the film so that the contents of volatile components consisting of organic solvents and generated water in the polyimide film to be finally obtained is preferably not more than 1 weight %.

The fixing equipment of the self-supporting film preferably used herein is, for example, equipped with a pair of belts or chains having a plurality of pins or holders at even intervals, along both side edges in the longitudinal direction of the solidified film supplied continuously or intermittently, and is able to fix the film while the pair of belts or chains are continuously or intermittently moved with movement of the film. In addition, the fixing equipment of the above solidified film may be able to extend or shrink the film under heat treatment with a suitable elongation percentage or shrinkage ratio in a lateral direction or a longitudinal direction (particularly preferably from about 0.5 to 5% of elongation percentage or shrinkage ratio).

Incidentally, the polyimide film having thermo-compression bonding property on both sides having particularly excellent dimensional stability may be obtained by heat-treating the polyimide film having thermo-compression bonding property on both sides produced in the above step again under low or no tension of preferably not higher than 4N and particularly preferably not higher than 3N at a temperature of 100 to 400° C. preferably for 0.1 to 30 minutes. In addition, the thus-produced lengthy polyimide film having thermo-compression bonding property on both sides may be rewound in a roll form by an appropriate known method.

The heating loss of the above self-supporting film refers to a value obtained by the following equation from the weight W1 measured before drying and the weight W2 measured after drying when the object film is dried at 420° C. for 20 minutes.

Heating Loss(% by mass)={(W1−W2)/W1}×100

Furthermore, the imide conversion ratio of the above self-supporting film is obtained by the method using a Karl Fischer's moisture meter as described in the Japanese Laid-open Patent Publication No. H09-316199.

A fine inorganic or organic additive may be added to the self-supporting film inside or surface layer thereof as needed. As the inorganic additive, there can be exemplified a particle-like or platelet-like inorganic filler. As the organic additive, there can be exemplified polyimide particles, particles of a thermosetting resin or the like. The amount and shape (size, aspect ratio) are preferably selected depending on the purpose of use.

Heating treatment can be performed by using various known equipments such as a hot air furnace, an infrared furnace or the like.

The one-sided or double-sided copper wiring polyimide film of the present invention can be used as a wiring material for a flexible printed circuit board (FPC), tape automated bonding (TAB), COF and the like.

### EXAMPLES

The present invention is now illustrated in detail below with reference to Examples. However, the present invention is not restricted to these Examples.

Physical properties were evaluated according to the following method.

1) Glass transition temperature (Tg) of polyimide film: It was determined from a peak tan δ value by a dynamic viscoelasticity method (tensile method; frequency: 6.28 rad/sec; temperature rising rate: 10° C./min).

2) Linear expansion coefficient (50 to 200° C.) of polyimide film: An average linear expansion coefficient at 20 to 200° C. was measured by a TMA method (tensile method; temperature rising rate: 5° C./min).

3) Peel strength of metal foil laminated polyimide film (as made), peel strength of polyimide film and adhesive film: In accordance with JIS-C6471, a lead with 3 mm in width (a sample piece) defined in the same test method was prepared, and for nine test pieces each from metal of roll inner side and roll outer side, the 90° peel strength was measured at a cross-head speed of 50 mm/min. For the polyimide film and the copper foil laminated polyimide film, its peel strength is an average of nine values. For the laminate of the polyimide film and the adhesive sheet, its peel strength is an average of three values. If the thickness of the metal foil is less than 5 μm, it is electroplated by 20 μm of thickness, and the measurement is carried out. (Roll inner means a peel strength of inside of the metal foil laminated polyimide film rewound, and roll outer means a peel strength of outside of the metal foil laminated polyimide film rewound.).

4) Inter-wiring insulation resistance, volume resistance of metal foil laminated polyimide film: They were measured in accordance with JIS-C6471.

5) Mechanical properties of polyimide film
Tensile strength: It was measured in accordance with ASTM-D882 (cross-head speed: 50 mm/min).
Elongation percentage: It was measured in accordance with ASTM-D882 (cross-head speed: 50 mm/min).
Tensile modulus: It was measured in accordance with ASTM-D882 (cross-head speed: 5 mm/min).

6) MIT bending resistance (polyimide film): A test piece with 15 mm in width across the full width was cut out in accordance with JIS-C6471, and the bending times were measured until the polyimide film was fractured at a curvature radius of 0.38 mm, a load of 9.8 N, a bending rate of 175 times/min and left/right flexing angle of 135 degrees.

### Reference Example 1

### Production Example of Thermo-Compression Bonding Multi-Layer Polyimide Film

In N-methyl-2-pyrrolidone, p-phenylenediamine (PPD) and 3,3′,4,4′-biphenyltetracarboxylic dianhydride (s-BPDA) were added in a molar ratio of 1,000:998 such that a monomer concentration was 18% (weight %, the same hereinafter). The resulting mixture was reacted at 50° C. for 3 hours to obtain a solution of a poly(amic acid) (a dope for heat resistant polyimide) having a solution viscosity of about 1,500 poises at 25° C.

On the other hand, to N-methyl-2-pyrrolidone, 1,3-bis(4-aminophenoxy)benzene (TPE-R) and 2,3,3′,4′-biphenyltetracarboxylic dianhydride (a-BPDA) were added in a molar ratio of 1,000:1,000 such that a monomer concentration was 22%. Further, triphenyl phosphate in 0.1% relative to the monomer weight was added thereto, and then the resulting mixture was continuously reacted at 5° C. for 1 hour to obtain a dope of a solution of a poly(amic acid) (a dope for thermo-compression bonding polyimide) having a solution viscosity of about 2,000 poises at 25° C.

The dope for heat resistant polyimide and the dope for thermo-compression bonding polyimide were flow-casted on a metal support by using a film-forming equipment provided with a three-layer extrusion die (multi-manifold type die) while varying a thickness of the three-layer extrusion die and continuously dried under hot air at 140° C. to form a solidified film. After peeling off this solidified film from the support, the solvent was removed by gradually heating from 200° C. to 450° C. in a heating furnace, and imidization was carried out, and the resulting long three-layer extrusion polyimide film was wound onto a wind-up roll. The resulting three-layer extrusion polyimide film exhibited the following physical properties.

(Thermo-Compression Bonding Multi-Layer Polyimide Film)
Thickness configuration: 3 μm/9 μm/3 μm (total 15 μm)
Coefficient of static friction: 0.37.
Tg of thermo-compression bonding polyimide: 240° C. (dynamic viscoelasticity method, peak tan δ value, the same hereinafter)
Tg of heat resistant polyimide: not less than 340° C.
Linear expansion coefficient (50 to 200° C.): 18 ppm/° C. (TMA method)
Tensile strength, elongation percentage: 460 MPa, 90% (ASTM-D882)
Tensile modulus: 7080 MPa (ASTM-D882)
MIT bending resistance: not fractured until 100,000 times

### Example 1

There was provided a double-sided copper foil with carrier laminate (product name: UPISEL N, a product of Ube Industries, Ltd.) in which electrolytic copper foils having a total thickness of 21 μm and formed by electrolytic copper plating to form thin copper foils (thickness: 3 μm) on carrier copper foil (thickness: 18 μm) are bonded by thermo-compression to both sides of a polyimide film (thickness: 25 μm) provided with thermo-compression bonding property. A layer of electrolytic copper foil with carrier on one side and a polyimide film layer were subjected to laser processing from one side of this double-sided copper foil with carrier laminate, whereby a hole for forming a blind via hole was formed. For laser processing, a UV-YAG laser (Model: 5320, Wavelength: 355 μm, a product of Electro Scientific Industries, Inc. (ESI, Inc.)) was used.

Subsequently, the via hole was subjected to the wet blast treatment at an air pressure of 0.2 MPa by means of a wet blasting apparatus (a product of Macoho Co., Ltd.) using a mixture of alumina particles and water (alumina concentration: 16 volume %) as an abrasive, and removal of burr and cleaning of the inside of the hole were carried out at the same time. Thereafter, the carrier foils on both sides were peeled off manually.

Next, a conductive film was formed by RISERTRON DPS Process manufactured by Ebara-Udylite Co., Ltd. and the conductive film was formed inside of the hole and on the copper foil. After degreasing and acid-washing, electrolytic copper plating was conducted in a copper sulfate bath with the thin copper foil as a cathode electrode at a current density of 2 A/dm² at 25° C. for 30 minutes, and a copper plating layer having a thickness of 7 μm was formed inside of the hole with the conductive film formed and on the copper foil.

After laminating a dry film-type negative photoresist (SPG-152, a product of Asahi Kasei Co., Ltd.) on the plated copper foil by a heat roll at 110° C., the portion to be a circuit (wiring pattern) and the portion to be a blind via hole were exposed to light and the unexposed resist was spray-developed with a 1% sodium carbonate aqueous solution at 30° C. for 20 seconds and removed. Subsequently, spray etching was performed with an aqueous ferric chloride solution at 50° C. for 10 seconds, then, the resist layer was peeled off by a spray treatment with an aqueous solution of 2% sodium hydroxide at 42° C. for 15 seconds. Thus, a polyimide film having 60 μm-pitch copper wirings on both sides thereof was obtained.

### Comparative Example 1

In Example 1, the carrier copper foils were peeled off after performing cleaning by the wet blast treatment. Instead, the carrier copper foils were peeled off before performing laser processing. In laser processing, a hole was formed on an electrolytic copper foil layer on one side and a polyimide film layer. Except these, a polyimide film having 60 μm-pitch copper wirings on both sides thereof was obtained in the same manner as in Example 1. Specific procedures are illustrated below.

Evaluation of Properties

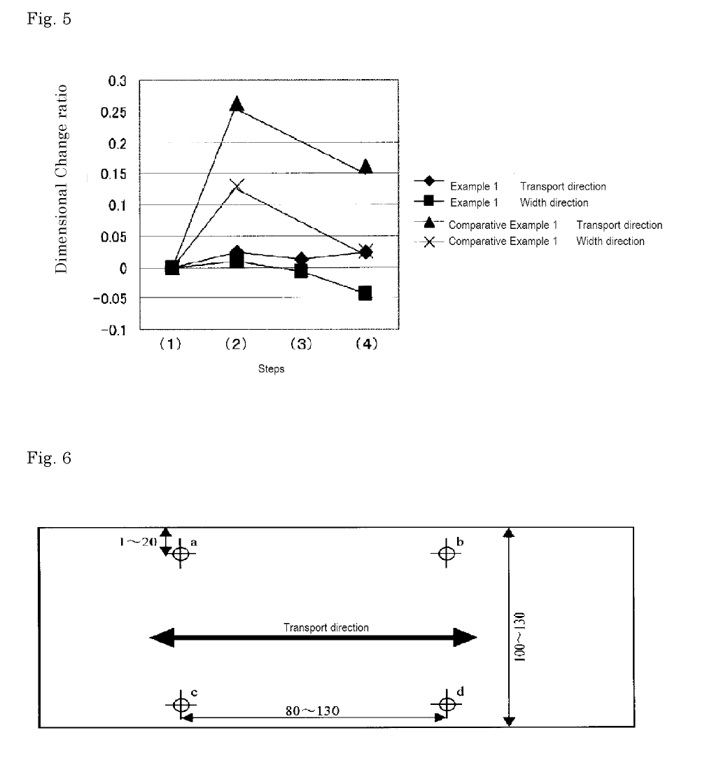

In Example 1 and Comparative Example 1, the dimensions of the base material after performing laser processing (1), after performing the wet blast treatment (2), after removing the carrier foils (3) and after removing the resist layer (4) were measured. The dimensional change ratio in the transport direction and in the width direction after respective steps are illustrated in Table 1, wherein the change ratios just after laser processing are set to 0. A graph with a horizontal axis indicating the steps and with a vertical axis indicating the change ratios in Table 1 is shown in FIG. 5. Herein, the change ratio measured after peeling off the resist layer (4) indicates the change ratio after patterning of wirings, and is considered to be an index representing overall positional and dimensional shifts.

Herein, the dimensional change ratios were measured in the following manner.

1) Reference points having a diameter of 40 to 200 μm were formed on the positions of the double-sided copper foil laminate with carrier as a base material having a width of 100 to 130 mm illustrated in FIG. 6 by laser processing.

2) The double-sided copper foil laminate with carrier subjected to laser processing was allowed to stand at a temperature of 23° C.±2° C. with a relative humidity of 50 to 60% for more than 20±4 hours, and then the distances between reference points at 4 places in FIG. 6 were measured with a measuring microscope capable of reading to 0.001 mm of a diameter value.

3) A circuit was formed in accordance with Example 1. After respective steps after performing the wet blast treatment, peeling off the carrier foils, and then peeling off the resist layer, the distances between reference points were measured in the same manner as in 2).

4) According to the following equation, the dimensional change ratio in the transport direction ΔLₘ (%) and the dimensional change ratio in the width direction ΔLₜ (%) were calculated.

$$Δ {L}_{m} = ( \frac{{A}_{2} - {A}_{1}}{{A}_{1}} + \frac{{D}_{2} - {D}_{1}}{{D}_{1}} ) \times \frac{1}{2} \times 100 \\ Δ {L}_{t} = ( \frac{{C}_{2} - {C}_{1}}{{C}_{1}} + \frac{{B}_{2} - {B}_{1}}{{B}_{1}} ) \times \frac{1}{2} \times 100 \qquad [ Equation 1 ]$$

Herein,

A₁: Distance (mm) between points a and b after performing laser processing

A₂: Distance (mm) between points a and b after performing respective steps

B₁: Distance (mm) between points b and d after performing laser processing

B₂: Distance (mm) between points b and d after performing respective steps

C₁: Distance (mm) between points c and a after performing laser processing

C₂: Distance (mm) between points c and a after performing respective steps

D₁: Distance (mm) between points d and c after performing laser processing

D₂: Distance (mm) between points d and c after performing respective steps

In Comparative Example 1, the dimensional change ratio in the transport direction after performing blast processing was large, i.e., 0.262%. In the polyimide film having copper wirings obtained after peeling off the resist layer, the dimensional change ratio in the transport direction was large, i.e., 0.161%, and further the dimensional change ratio in the width direction was small, i.e., 0.025%, indicating the directional anisotropy of extension. As compared to Comparative Example 1, in Example 1, the dimensional stability was excellent from the facts that the absolute values of the dimensional change ratios in the transport direction and in the width direction in all steps were within 0.05%, and the anisotropy in the extension direction was small,

TABLE 1
Dimensional change ratio [%]

| | | | Comparative | Comparative |
|---|---|---|---|---|
| | Example 1 | Example 1 | Example 1 | Example 1 |
| | Transport | Width | Transport | Width |
| | direction | direction | direction | direction |
| | (ΔLₘ) | (ΔLₜ) | (ΔLₘ) | (ΔLₜ) |
| (1) After | 0 | 0 | 0 | |
| performing | | | | |
| laser | | | | |
| processing | | | | |
| (2) After | 0.024 | 0.009 | 0.262 | 0.13 |
| performing | | | | |
| the wet blast | | | | |
| treatment | | | | |
| (3) After | 0.012 | −0.007 | — * | — * |
| peeling off the | | | | |
| carrier foils | | | | |
| (4) After | 0.024 | −0.043 | 0.161 | 0.025 |
| peeling off the | | | | |
| resist layer | | | | |

* the carrier foils are peeled off before performing laser processing so that blanks are given to the cells of “After peeling off the carrier foils in Comparative Example 1”.

### Comparative Example 2

There was provided a double-sided copper foil laminate (product name: UPISEL N, a product of Ube Industries, Ltd.) in which electrolytic copper foils having a thickness of 9 μm are bonded by thermo-compression on both sides of a polyimide film (thickness: 25 μm) provided with thermo-compression bonding property. A layer of electrolytic copper foil on one side and a polyimide film layer were subjected to laser processing from one side of this double-sided copper foil laminate, whereby a hole for forming a blind via hole was formed. For laser processing, a UV-YAG laser (Model: 5320, Wavelength: 355 μm, a product of Electro Scientific Industries, Inc. (ESI, Inc.)) was used.

Subsequently, the via hole was subjected to the wet blast treatment at an air pressure of 0.2 MPa by means of a wet blasting apparatus (a product of Macoho Co., Ltd.) using a mixture of alumina particles and water (alumina concentration: 16 volume %) as an abrasive, and removal of burr and cleaning of the inside of the hole were carried out at the same time to obtain a base material having a via hole after performing the wet blast treatment (no etching). The dimensional change ratio (%) of the base material having a via hole obtained after performing the wet blast treatment (no etching) were measured and the results thereof are shown in Table 2 (Herein, in the measurement of the dimensional change ratios (%), the dimensional change ratios after performing laser processing were set to 0.).

### Example 2

In the base material having a via hole obtained after performing the wet blast treatment (no etching) in Comparative Example 2, the copper foils on both sides were etched by 7 μm in thickness using DP-200 manufactured by Ebara-Udylite Co., Ltd. as an etching solution, whereby an etching-processed base material having a via hole was obtained. The dimensional change ratios (%) of the resulting etching-processed base material having a via hole were measured and the results thereof are shown in Table 2 (Herein, in the measurement of the dimensional change ratios (%), the dimensional change ratios after performing laser processing were set to 0.).

### Example 3

In the base material having a via hole obtained after performing the wet blast treatment (no etching) in Comparative Example 2, the copper foils on both sides were etched by 1 μm in thickness using DP-200 manufactured by Ebara-Udylite Co., Ltd. as an etching solution, whereby an etching-processed base material having a via hole was obtained. The dimensional change ratios (%) of the resulting etching-processed base material having a via hole were measured and the results thereof are shown in Table 2 (Herein, in the measurement of the dimensional change ratios (%), the dimensional change ratios after performing laser processing were set to 0.).

In the base material subjected to the wet blast treatment alone without etching (Comparative Example 2), the extension is large such that the dimensional change ratio in the transport direction is 0.086% and the dimensional change ratio in the width direction is 0.059%. In Examples 2 and 3 in which the base material of Comparative Example 2 was subjected to etching to remove the protection layer on the surface, the absolute values of the dimensional change ratio in the transport direction and the dimensional change ratio in the width direction are small as compared to the base material of Comparative Example 2 without etching, thus the extension is small. In particular, in the base material of Example 3 (7 μm thickness was etched), the excellent effect is obtained such that the extension is further small.

TABLE 2
Dimensional change ratio [%]

| | | | | | Comparative | Comparative |
|---|---|---|---|---|---|---|
| | Example 2 | Example 2 | Example 3 | Example 3 | Example 2 | Example 2 |
| | Transport | Width | Transport | Width | Transport | Width |
| | direction | direction | direction | direction | direction | direction |
| | (ΔLₘ) | (ΔLₜ) | (ΔLₘ) | (ΔLₜ) | (ΔLₘ) | (ΔLₜ) |
| After performing | 0 | 0 | 0 | 0 | 0 | 0 |
| laser processing | | | | | | |
| After performing | 0.086 | 0.059 | 0.086 | 0.059 | 0.086 | 0.059 |
| the wet blast | | | | | | |
| treatment | | | | | | |
| (no etching) | | | | | | |
| After performing | 0.043 | 0.033 | 0.079 | 0.056 | — | — |
| etching | | | | | | |

### INDUSTRIAL APPLICABILITY

The present invention provides a method for producing a printed wiring board having high dimensional stability with high productivity.

1. A method for producing a printed wiring board comprising:
providing a metal laminate in which a metal layer having an inner metal layer portion and a protection layer portion is laminated on at least one side of an insulating resin layer, whereby the inner metal layer portion is arranged on the side of the insulating resin layer;
forming a via hole on the metal layer and the insulating resin layer;
performing blast processing after forming the via hole; and
removing the protection layer portion after performing blast processing.

2. The method according to claim 1, wherein the metal layer has a structure in which the inner metal layer portion and the protection layer portion are laminated as different layers, and the protection layer portion is removed by peeling off or etching after performing blast processing.

3. The method according to claim 2, wherein the protection layer portion is selected from the group consisting of resin, metal, and a multi-layer structure of a resin and a metal.

4. The method according to claim 2, wherein the metal layer is a copper foil with carrier foil.

5. The method according to claim 1, wherein in the metal layer, the inner metal layer portion and the protection layer portion are present as an indistinguishable single layer, wherein the protection layer portion is removed by etching.

6. The method according to claim 1, wherein a thickness of the protection layer portion is determined such that the absolute value of the dimensional change ratio just after removing the protection layer portion is not more than 0.07% as compared to the dimension measured just after forming the via hole.

7. The method according to claim 1, wherein a thickness of the protection layer portion is determined such that the absolute value of the dimensional change ratio when completing a wiring pattern is not more than 0.07% as compared to the dimension measured just after forming the via hole.

8. The method according to claim 1, wherein a thickness of the protection layer portion is not less than 2 μm.

9. The method according to claim 1, wherein the metal laminate has the metal layers laminated on both sides of the insulating resin layer, and after removing the protection layer, formation of the wiring pattern and electrical connection between wirings present on both sides of the insulating resin layer through the via hole are carried out.

10. The method according to claim 1, wherein the insulating resin layer is obtained by laminating a thermo-compression bonding polyimide layers on both sides of a high heat resistant aromatic polyimide layer into one body.

11. A copper wiring polyimide film produced by the method according to claim 10.
